(19) United States
(12) Patent Application Publication
(10) Pub. No.: US 2021/0241544 A1
(43) Pub. Date: Aug. 5, 2021

(54) PLATFORM FOR ANALYZING HEALTH OF HEAVY ELECTRIC MACHINE AND ANALYSIS METHOD USING THE SAME

(71) Applicant: PACT-ALLIANCE CO. LTD, Dangjin-si (KR)

(72) Inventor: Sang Hun LEE, Gyeongsan-si (KR)

(73) Assignee: PACT-ALLIANCE CO. LTD, Dangjin-si (KR)

(21) Appl. No.: 17/239,122

(22) Filed: Apr. 23, 2021

Related U.S. Application Data
(63) Continuation-in-part of application No. PCT/KR2020/013533, filed on Oct. 6, 2020.

(30) Foreign Application Priority Data
Oct. 7, 2019 (KR) 10-2019-0123584

(51) Int. Cl. G07C 3/00; G07C 3/02; G05B 23/02; G06F 16/9035; G06N 20/00

(52) U.S. Cl. CPC G07C 3/005; G07C 3/02; G06N 20/00; G06F 16/9035; G05B 23/0283

(57) ABSTRACT

Provided is an analyzing method using a platform for analyzing health of a heavy electric machine. The method includes inputting on-site diagnosis information in which pieces of data collected in a site are received in a state in which operation of the heavy electric machine stops, collecting pieces of online sensor data in which pieces of data of installed sensors are periodically/discontinuously collected through a sensor module and a data collection module, building a database using the data in the inputting of the on-site diagnosis information and the data in the collecting of the pieces of online sensor data, analyzing of the current standard health of the heavy electric machine, and automatically determining a diagnosis result.

### CROSS-REFERENCE TO RELATED APPLICATIONS

This application is a Continuation-in-Part of International Application No. PCT/KR2020/013533 filed Oct. 6, 2020, which claims benefit of priority to Korean Patent Application No. 10-2019-0123584 filed Oct. 7, 2019, the entire content of which is incorporated herein by reference.

### BACKGROUND

### 1. Field of the Invention

The present invention relates to a platform for analyzing health of a heavy electric machine and an analysis method using the same.

### 2. Discussion of Related Art

For aging heavy electric machines such as generators, transformers, and electric motors, the probability of failure and the probability of insulation breakdown increase. In particular, in the case of electric motors, electric motors that have operated for ten years or more account for most insulation breakdown. For many power plants and large-scale plants in operation, ten years has passed since completion of construction, and heavy electric machines are already undergoing aging.

A heavy electric machine is an important machine in operation of a power generation facility and causes a serious problem such as power generation shutdown in the event of a failure, and when insulation breakdown occurs, not only are recovery costs incurred but also a loss of profits due to a power supply failure occurs and there are cases in which peripheral facilities are also lost.

A current standard analysis method and system, in which pieces of data actually measured in sites are evaluated, evaluates all heavy electric machines on the basis of a fixed absolute standard. However, heavy electric machines have different characteristics for each manufacturer but heavy electric machines of the same manufacturer also have different characteristics depending on the manufacturing timing and there is a disadvantage in that it is difficult to predict a failure with an absolute current standard analysis method due to such characteristics. Moreover, since the current standard analysis method or system, in which the data is evaluated in sites, stores the data separately and does not manage history, it is inconvenient in various ways in terms of managing health history data.

In addition, it is very inconvenient to proceed with work because a plant company, a test company, a test equipment company, a test expert, etc., which are parties interested in analysis of health of the heavy electric machine, are in contact with each other and perform work individually.

### SUMMARY OF THE INVENTION

The present invention is directed to providing a platform for analyzing health of a heavy electric machine, in which various types of data related to a test for the heavy electric machine are managed and a time of failure is predicted using the same, and an analysis method using the same.

According to an aspect of the present invention, there is provided a platform for analyzing health of a heavy electric machine. The platform includes a sensor module (210), a data collection module (220) configured to collect pieces of data from the sensor module (210), a data management module (400) configured to receive and manage pieces of data from the data collection module (220), a database module (500) configured to record the pieces of data received from the data management module (400), and a diagnosis and analysis module (600) configured to perform diagnosis of an electric motor by applying the pieces of data recorded in the database module (500). The diagnosis and analysis module (600) includes a current standard insulation diagnosis system (610) configured to diagnose health of the electric machine on the basis of the pieces of received data, a trend-based health analysis system (620) configured to estimate and analyze a predicted trend for each year in conjunction with a database of the database module (500), a degradation prediction simulation and analysis system (630) configured to generate a simulation model and analyze degradation, and an online sensor data analysis system (640) configured to analyze using the provided online data.

The platform may further include a payment module (110) configured to perform payment between external users, a report and data management module (120) configured to collect and/or provide reports and pieces of data from and/or to the external users, and a warning module (130) configured to warn the outside about an event when the event occurs.

The sensor module (210) may include a mounting sensor (211), diagnosis equipment (212), and a system sensor (213) which are mounted on the heavy electric machine, and the data collection module (220) may include a PI system (221) configured to collect pieces of data of the mounting sensor (211), a general diagnosis system (222) linked with the diagnosis equipment (212), and a transducer (223) linked with the system sensor (213).

The database module (500) may include an electric motor specification database (510), an insulation diagnosis database (520), a failure history database (530), an online sensor database (540), and a health determination database (550).

The trend-based health analysis system (620) may estimate a predicted trend for each year by estimating the same type of heavy electric machine data parameters using a target electric motor data parameter and the insulation diagnosis database (520).

The degradation prediction simulation and analysis system (630) may include a simulation model and a machine learning-based degradation estimation modeling.

The constructed machine learning-based degradation estimation modeling may be modeling in which each piece of individual data is expressed in a unit space (Mahalanobis space (MS)) based on a normal group center point and then it is determined that the pieces of data are normal or abnormal by measuring a unit distance (Mahalanobis distance (MD)) indicating how far the pieces of data are from the center point.

Independent variables of the each piece of individual data may include a value of an insulation resistance measured for one minute, a value of polarity index determination, a value of a polarity index, a value of dielectric loss tangent determination, a value of a dielectric loss tangent, a value of alternating current (AC) determination, a value of an AC, a value of partial high voltage determination, and a value of a partial discharge high voltage.

The online sensor data analysis system (640) may extract a value of a discharge pattern from the pieces of online sensor data collected in the data collection module (220) and estimate a risk and a cause of occurrence according to the discharge pattern.

According to another aspect of the present invention, there is provided a method of analyzing health of a heavy electric machine. The method includes an operation (S100) of inputting on-site diagnosis information in which pieces of data collected in a site are received in a state in which operation of the heavy electric machine stops, an operation (S200) of collecting pieces of online sensor data in which pieces of data of installed sensors are periodically/discontinuously collected through a sensor module (210) and a data collection module (220), an operation (S400) of building a database using the data in the operation (S100) of the inputting of the on-site diagnosis information and the data in the operation (S200) of the collecting of the pieces of online sensor data, an operation (S300) of analyzing the current standard health which includes an operation (S310) of analyzing a direct current test, an operation (S320) of analyzing an alternating current test, an operation (S330) of analyzing a dielectric loss tangent test, and an operation (S340) of analyzing a partial discharge test and in which health of a current standard heavy electric machine is diagnosed based on the pieces of data input in the operation (S100) of the inputting of the on-site diagnosis information, an operation (S500) of analyzing trend-based health in which a predicted trend for each year is estimated in connection with the database built in the operation (S400) of the building of the database and the health is analyzed, an operation (S600) of analyzing degradation prediction simulation in which a simulation model is generated and the health of the heavy electric machine is analyzed, an operation (S700) of analyzing the pieces of online sensor data in which the health of the heavy electric machine is analyzed using the pieces of online sensor data collected in the operation (S200) of the collecting of the online sensor data, and an operation (S800) of automatically determining a diagnosis result.

In the operation (S300) of the analyzing of the current standard health, the current standard health may be analyzed using the pieces of data input in the operation (S100) of the inputting of the on-site diagnosis information, in the operation (S500) of the analyzing of the trend-based health, the trend-based health may be analyzed using the pieces of data input in the operation (S100) of the inputting of the on-site diagnosis and the pieces of data of the heavy electric machine which are the same type as those of the field diagnosed heavy electric machine, and in the operation (S600) of the analyzing of the degradation prediction simulation, the degradation prediction simulation may be analyzed using the pieces of data input in the operation (S100) of the inputting of the on-site diagnosis, the pieces of data of the heavy electric machine which are the same type as those of the field diagnosed heavy electric machine, and the pieces of data of the heavy electric machine of the same manufacturer as and a similar period to the field diagnosed heavy electric machine.

The operation (S200) of the collecting of the online sensor data may include an operation (S211) of classifying the pieces of collected sensor data in which the pieces of collected sensor data collected online are classified into data for each target heavy electric machine, an operation (S212) of organizing time and/or daily trends in which the trends are organized so as to be analyzed by time and date, an operation (S213) of inspecting a reference and an event in which values of the sensors are firstly determined and an event is detected, and an operation (S214) of warning when an event occurs in which a warning is generated when the event occurs.

The database built in the operation (S400) of the building of the database may include a heavy electric machine specification database (510), an insulation diagnosis database (520), a failure history database (530), an online sensor database (540), and a health determination database (550).

The operation (S500) of the analyzing of the trend-based health may include an operation (S510) of classifying basic information of the heavy electric machine using the insulation diagnosis database, an operation (S520) of extracting a measurement result of a target heavy electric machine, an operation (S530) of reviewing a maintenance history, an operation (S540) of estimating a target electric motor data parameter, an operation (S550) of estimating the same type of heavy electric machine data parameters using the insulation diagnosis database, an operation (S560) of estimating a machine learning-based parameter using the insulation diagnosis database, an operation (S570) of verifying suitability of the corresponding parameter using the insulation diagnosis database, an operation (S580) of estimating a predicted trend for each year, and an operation (S590) of predicting degradation based on a current standard.

The operation (S600) of the analyzing of the degradation prediction simulation may include an operation (S610) of analyzing raw data of the heavy electric machine, an operation (S620) of analyzing start and/or stop and event occurrence weight in which the pieces of online data collected in the operation (S200) of the collecting of the online sensor data are added, an operation (S630) of generating a simulation model, an operation (S640) of adjusting optimal values of parameters of the simulation model generated in the operation (S630) of the generating of the simulation model, an operation (S650) of determining the simulation model in which the model is determined with the values adjusted in the operation (S640) of the adjusting of the optimal values of the parameter, an operation (S660) of tracking a degradation relationship in which a relationship of the event is tracked based on the result values analyzed in the operation (S620) of the analyzing of start and/or stop and event occurrence weight, an operation (S670) of estimating conditional failure probability in which failure probability is estimated using the simulation model determined in the operation (S650) of the determining of the simulation model, an operation (S680) of building a machine learning-based degradation estimation modeling in which a machine learning-based degradation modeling is built, and an operation (S690) of building a degradation prediction simulation in which a final simulation is completed using the simulation model determined in the operation (S650) of the determining of the simulation model and the machine learning-based degradation estimation modeling determined in the operation (S680) of the building of the machine learning-based degradation estimation modeling.

In the operation (S680) of the building of the machine learning-based degradation estimation modeling, modeling may be formed in which each piece of individual data is expressed in a unit space (Mahalanobis space (MS)) based on a normal group center point and then it is determined that the pieces of data are normal or abnormal by measuring a unit distance (Mahalanobis distance (MD)) indicating how far the pieces of data are from the center point.

Independent variables of the each piece of individual data may include a value of an insulation resistance measured for one minute, a value of polarity index determination, a value of a polarity index, a value of dielectric loss tangent determination, a value of a dielectric loss tangent, a value of alternating current determination, a value of an alternating current, a value of partial high voltage determination, and a value of a partial discharge high voltage.

In the operation (S700) of the analyzing of the online sensor data, a value of a discharge pattern may be extracted from the pieces of online sensor data collected in the operation (S200) of the collecting of the online sensor data and a risk and a cause of occurrence may be estimated according to the discharge pattern.

The method may further include an operation (S900) of converting a determining result data for re-applying the result determined in the operation (S800) of the automatic determining of the diagnosis result to the operation (S400) of the building of the database.

The simulation model generated in the operation (S600) of the analyzing of the degradation prediction simulation may be updated to a more sophisticated model by a model and data-driven approach using the data generated in the operation (S900) of the converting of the determining result data.

### BRIEF DESCRIPTION OF THE DRAWINGS

The patent or application file contains at least one drawing executed in color. Copies of this patent or patent application publication with color drawing(s) will be provided by the Office upon request and payment of the necessary fee.

The above and other objects, features and advantages of the present invention will become more apparent to those of ordinary skill in the art by describing exemplary embodiments thereof in detail with reference to the accompanying drawings, in which:

FIG. 1 is a conceptual diagram illustrating a configuration of a heavy electric machine health analysis platform according to an embodiment of the present invention;

FIG. 2 is a conceptual diagram illustrating some components of the heavy electric machine health analysis platform according to the embodiment of the present invention;

FIG. 3 is a conceptual diagram illustrating a configuration of a heavy electric machine health analysis platform according to another embodiment of the present invention;

FIG. 4 is a conceptual diagram illustrating some components of the heavy electric machine health analysis platform according to another embodiment of the present invention;

FIG. 5 is a conceptual diagram illustrating some components of the heavy electric machine health analysis platform according to another embodiment of the present invention;

FIG. 6 is a conceptual diagram illustrating some components of the heavy electric machine health analysis platform according to another embodiment of the present invention;

FIG. 7 is a flowchart illustrating an analysis method of the heavy electric machine health analysis platform according to another embodiment of the present invention;

FIG. 8 is a flowchart illustrating current standard health determination in the analysis method of the heavy electric machine health analysis platform according to another embodiment of the present invention;

FIG. 9 is a conceptual diagram illustrating a database module applied to the analysis method of the heavy electric machine health analysis platform according to another embodiment of the present invention;

FIG. 10 is a flowchart illustrating trend-based health analysis in the analysis method of the health analysis system according to another embodiment of the present invention;

FIGS. 11A and 11B are graphs showing models obtained by the trend-based health analysis according to the embodiment of FIG. 10;

FIG. 12 is a flowchart illustrating degradation prediction simulation analysis in the analysis method of the health analysis system according to another embodiment of the present invention;

FIGS. 13A to 13C are graphs showing results of online sensor data analysis in the analysis method of the health analysis system according to another embodiment of the present invention;

FIGS. 14A to 14L are graphs showing results of the online sensor data analysis in the analysis method of the health analysis system according to another embodiment of the present invention; and

FIG. 15 is a flowchart illustrating data conversion of determination results in the analysis method of the health analysis system according to another embodiment of the present invention.

FIG. 16A is a graph showing tan δ voltage characteristic according to another embodiment of the present invention;

FIG. 16B is slot discharge according to another embodiment of the present invention;

FIG. 16C is a graph showing tan δ voltage characteristic according to another embodiment of the present invention;

### DETAILED DESCRIPTION OF EXEMPLARY EMBODIMENTS

Hereinafter, embodiments disclosed in this specification will be described in detail with reference to the accompanying drawings. Identical or similar elements are denoted by the same reference numerals, and redundant description thereof will be omitted. A suffix “module,” “unit,” “part,” or “portion” of an element used herein is assigned or incorporated for convenience of specification description, and the suffix itself does not have a distinguished meaning or function. Further, in descriptions of the embodiments disclosed in this specification, when detailed descriptions of related known configurations or functions are deemed to unnecessarily obscure the gist of the present invention, they will be omitted. Further, the accompanying drawings are only examples to facilitate overall understanding of the embodiments disclosed in this specification and the technological scope disclosed in this specification is not limited to the accompanying drawings. It should be understood that the present invention covers all modifications, equivalents, and alternatives falling within the spirit and scope of the present invention.

It will be understood that when an element is referred to as being “connected” or “coupled” to another element, it can be directly connected or coupled to the other element or intervening elements may be present. In contrast, it will be understood that when an element is referred to as being “directly connected” or “directly coupled” to another element, there are no intervening elements present.

As used herein, the singular forms “a,” “an,” and “the” are intended to also include the plural forms, unless the context clearly indicates otherwise.

In addition, throughout this specification, when a certain part “includes” a certain element, it means that another element may be further included not excluding another element unless otherwise defined.

It should be clear to those skilled in the art that the present invention may be embodied in other specific forms without departing from the spirit or essential features thereof.

Hereinafter, the embodiments of the present invention will be described in detail with reference to the accompanying drawings. Like reference numerals in the drawings denote like elements.

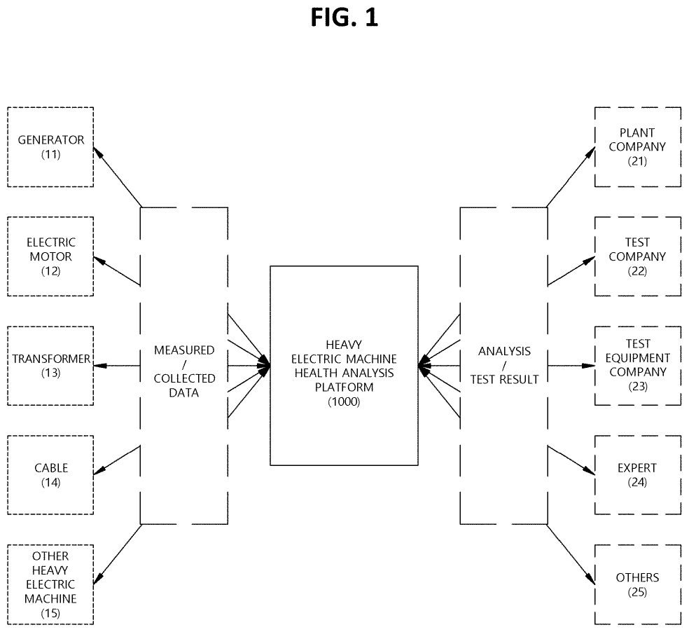

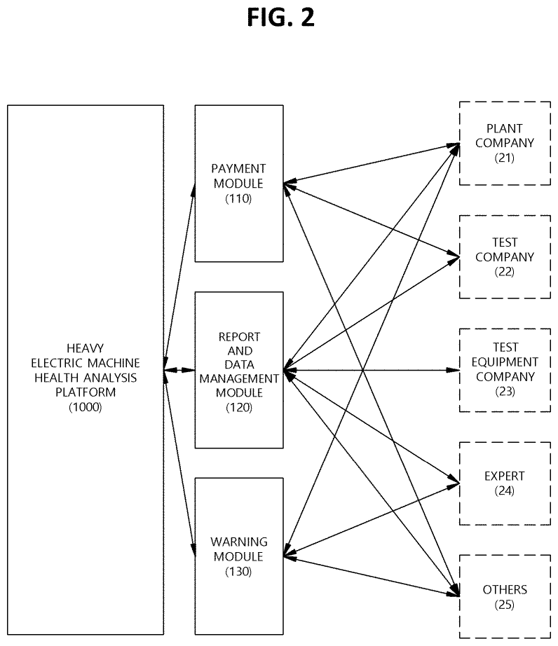

Configuration of system FIG. 1 is a conceptual diagram illustrating a configuration of a heavy electric machine health analysis platform according to an embodiment of the present invention. FIG. 2 is a conceptual diagram illustrating some components of the heavy electric machine health analysis platform according to the embodiment of the present invention.

Referring to FIG. 1, a heavy electric machine health analysis platform 1000 according to the present embodiment is connected to a plurality of heavy electric machines 11, 12, 13, 14, and 15 and receives pieces of data, which are measured or collected by a direct input through a terminal or are measured or collected through an online path. Further, the heavy electric machine health analysis platform 1000 is connected to a plant company 21, a health analysis and test company 22, a test equipment company 23, an expert 24, and other groups 25 and performs tasks, such as payment, which is related to a request for analysis, management, and price, and data inquiry and analysis result inquiry on the basis of test results.

The platform according to the present embodiment may allow companies participating in the heavy electric machine health analysis to share and manage pieces of data related to each machine and conduct business processes according to the health analysis in one platform, and thus it is possible to efficiently share the data and analysis results and to rapidly proceed with necessary actions.

Referring to FIG. 2, the heavy electric machine health analysis platform 1000 according to the present embodiment further includes a payment module 110, a report and data management module 120, and a warning module 130 in addition to components for a health analysis system which will be described below. The plant company 21 may directly request a test through the platform, may perform payment services through the payment module 110, perform data verification and expert advice (action plan) through the report and data management module 120, and provide a solution using artificial intelligence. The plant company 21 may perform and expert training request through functions provided by the platform.

The test company 22 may secure public confidence of test data according to the evaluation of expert and artificial intelligence by securing data through the report and data management module 120, and perform payment through the payment module 110. Further, the test company may secure short-range test objects by receiving a location-based order using information that may be obtained from the report and data management module 120. In particular, by using a function for managing data, which is provided by the platform, it is possible to improve a data input method in a past conventional computer from the form of an application or a notebook input method to an automatic input method.

The test equipment company 23 may also directly receive the data through the report and data management module 120 to share accurate technical data.

The expert 24 may effectively input and obtain data through the report and data management module 120 and may receive various alarms through the warning module 130.

Examples of items of the heavy electric machine that may be tested in the present embodiment are as follows.

TABLE 1
Test items of heavy electric machine

| Target machines | Test items | | | | |
|---|---|---|---|---|---|
| Generator | Insulation | RSO (rotor short) | ELCID (iron core | Wedge tightness | Online PD |
| | diagnosis | | health test) | (wedge test) | |
| Electric motor | Insulation | Online PD | | | |
| | diagnosis | | | | |
| Transformer | DGA (dissolved | PF (insulation | SFRA (mechanical | Insulator | |
| | gas analysis) | degradation) | deformation) | moisture content | |
| | | | | measurement | |
| Cable | Insulation | | | | |
| | diagnosis | | | | |

Referring to Table 1, insulation diagnosis of a generator, an electric motor, and a cable may start by methods using insulation resistance, polarity index, alternating current (AC), dielectric loss tangent, partial discharge, etc. according to a diagnosis method applied in the present embodiment to be described below. However, in the case of a cable, only insulation resistance and dielectric loss tangent may be measured. In the platform of the present embodiment, dissolved gas analysis (DGA) may be specifically applied to a transformer. Specifically, by managing history of temperature values at the time of measurement on dissolved gases that may be measured, that is, H₂, CH₄, C₂H₂, C₂H₄, C₂H₆, CO, CO₂, TDCG, O₂, and N₂, DGA results may be analyzed using a graph. In addition, insulation degradation (PF), sweep frequency response analysis (SFRA, mechanical deformation), and insulator moisture content measurement values of the transformer may be further analyzed.

In the platform of the present embodiment, the generator may additionally receive values of a recurrent surge oscillography (RSO) test, electromagnetic core imperfection detection (ELCID) test, and wedge tightness test in addition to the insulation diagnosis. It is possible to receive an input through separate test equipment or to receive values from on-site measurement together with the data. In the case of using the separate test equipment, data is received through a data file or a built application interface (API).

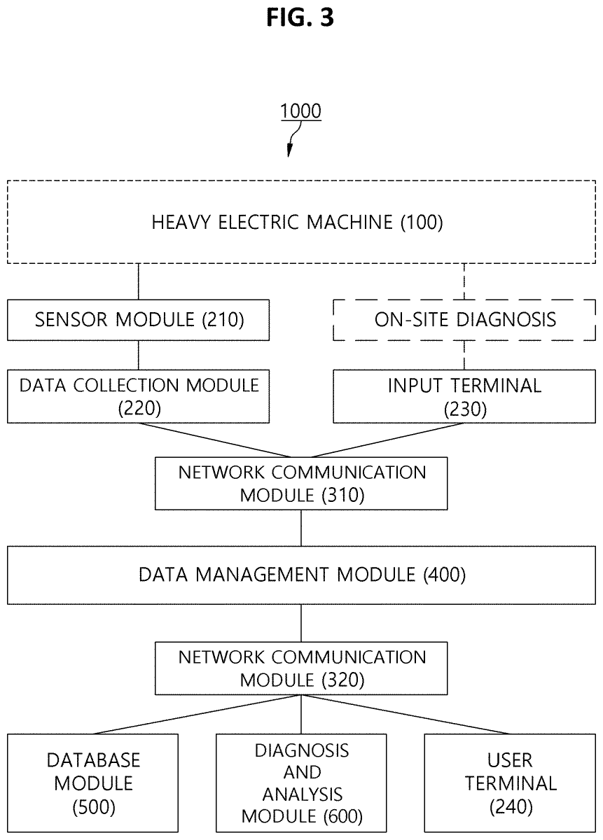

FIG. 3 is a conceptual diagram illustrating a configuration of a heavy electric machine health analysis platform according to another embodiment of the present invention.

Referring to FIG. 3, a heavy electric machine health analysis platform 1000 according to the present embodiment includes a sensor module 210, a data collection module 220 which collects data from the sensor module 210 and transmits the data by processing the data when processing is required, an input terminal 230, network communication modules 310 and 320, a data management module 400, a database module 500, a diagnosis and analysis module 600, and a user terminal 240.

The sensor module 210 measures data representing a state of the heavy electric machine in the form of an individual sensor or diagnostic device, and the pieces of data are collected and processed by the data collection module 220. The data collection module 220 transmits the pieces of data to the data management module 400 through the network communication module 310. The measurement values measured by periodic diagnosis may be transmitted to the data management module 400 through the input terminal 230. The data management module 400 classifies the pieces of data and transmits and stores the pieces of data to and in the database module 500. Based on the stored data, health analysis is performed by applying each diagnosis algorithm of the diagnosis and analysis module 600. Inquiry about results of the analysis may be made through the user terminal 240 or a separate warning may be received when there is an abnormal state. Hereinafter, each component will be described in detail.

(a) Sensor Configuration and Data Collection Module

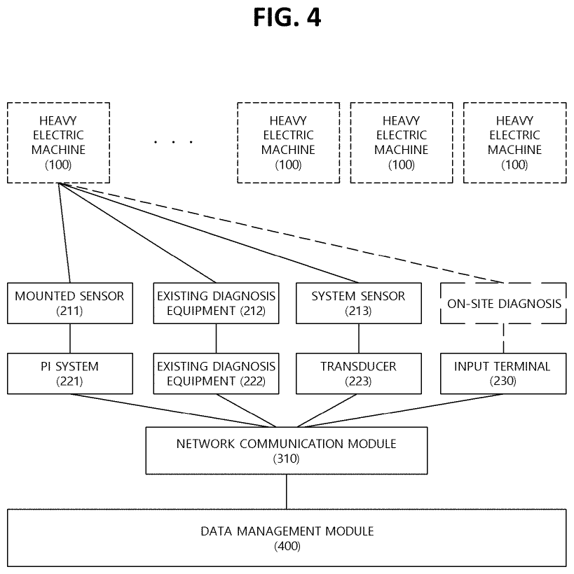

FIG. 4 is a conceptual diagram illustrating some components of the heavy electric machine health analysis platform according to another embodiment of the present invention.

Referring to FIG. 4, the heavy electric machine health analysis platform according to the present embodiment simultaneously analyzes a plurality of electric motors. Generally, an analysis system is connected to at least 30 electric motors to analyze health of the electric motors.

The embodiment of FIG. 4 is different from the embodiment of FIG. 3 in that each of a sensor module 210 and a data collection module 220 is provided with a plurality of devices. Sensors may collect pieces of data from previously mounted sensors and in order to obtain data characteristics of history data analysis, a system sensor may be additionally mounted to analyze the pieces of data.

In one heavy electric machine 100, various types of online and offline sensors are mounted. For example, electric motors of a power plant already have a sensor 211 mounted for measuring an internal winding temperature on-line. A PI system 221 for collecting and processing data from the mounted sensors 211 is constructed. The corresponding data should be requested and/or collected using a driver provided by a manufacturer.

In addition, on-line diagnosis equipment 212 other than the sensors may be installed and the equipment may collect data in its own way. In order to receive the data of the corresponding equipment, a driver or protocol document provided by the manufacturer should be present. The pieces of data may be obtained via an existing diagnosis system 222.

Therefore, when the mounting sensors 211, which are sensors that are already mounted on the heavy electric machine 100, are present and there is separate diagnosis equipment 212 applied to the heavy electric machine 100, the pieces of data may be additionally obtained. The pieces of data are intended to obtain more accurate results using the sensors already installed in the existing system.

Unlike the above configuration, in the present embodiment, a separate system sensor 213 is provided. The system sensor 213 is installed in a health analysis system 1000 according to the present embodiment and is additionally mounted on the heavy electric machine 100. The system sensor 213 collects data through a transducer 223.

For example, the system sensor 213 may be a temperature sensor. In particular, unlike other analysis systems, the health analysis system 1000 of the present embodiment may not analyze data at a specific time point but may analyze the health by analyzing history of the pieces of measured data and may measure a temperature with optimal sensing that may utilize the pieces of data. The pieces of data of the sensors are collected and/or processed separately from the previously constructed system. Detailed sensing algorithms and analysis will be described below.

(b) Database Module

The database module 500 stores and/or manages insulation diagnosis data. The database module 500 may be implemented in separate hardware or may be implemented by being integrated into the data management module 400. In particular, the database module 500 may store information related to specifications of the heavy electric machine, such as a manufacturer/manufacturing date/serial number, a result of insulation diagnosis of the heavy electric machine, failure/maintenance history of the heavy electric machine, and a result of measurement of the sensor. The database module 500 may include an automatic backup database to protect the data from unexpected accidents.

Further, in the database module 500, various types of data transmitted from the sensor module 210 are built as databases and the pieces of data are applied to a history management system. This has an effect of preventing the occurrence of a failure or the like that may occur during operation in the system that regularly manages the health of the heavy electric machine in a state in which the heavy electric machine is stopped.

(c) Network Communication Module

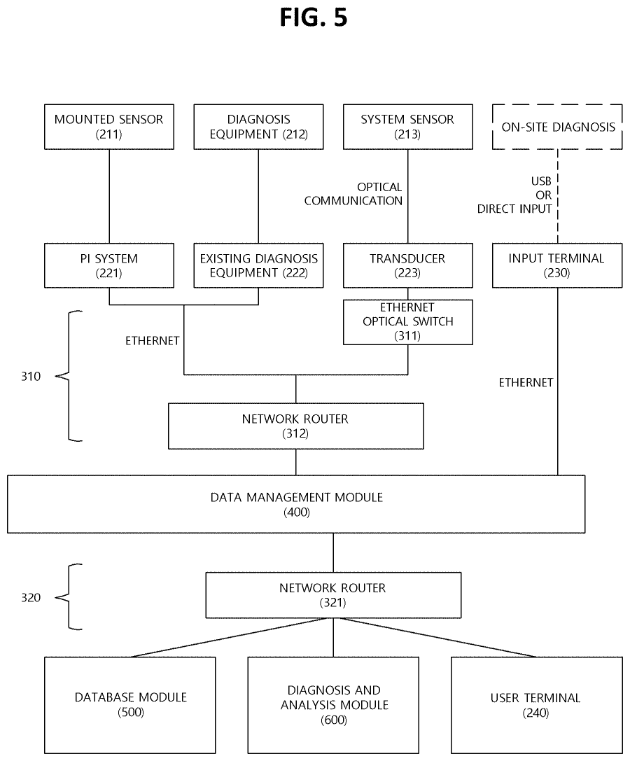

FIG. 5 is a conceptual diagram illustrating some components of the heavy electric machine health analysis platform according to another embodiment of the present invention.

Referring to FIG. 5, in the present embodiment, each of the network communication modules 310 and 320 may be individually implemented. The network communication modules 310 and 320 may be implemented in various ways as a unit for data communication of the system.

As a communication network, Ethernet is basically used, and an appropriate solution using a general Ethernet hub or an optical switch is applied according to a distance and data transmission amount. In particular, since the electric motors 100 measured in the present embodiment may be constructed in an environment in which 30 or more electric motors 100 communicate with a plurality of sensors, a communication network capable of establishing a plurality of channels is configured.

Referring to FIG. 5 again, as an implementation of the above type, the existing PI system 221, the existing diagnosis system 222, and the data management module 400 constitute a communication network via Ethernet and communicate with the data management module 400 through a network router 312. The system sensor 213 communicates with the transducer 223 through optical communication, is connected to the network router 312 through a separate Ethernet pipe switch 311, and transmits data to the data management module 400. In the case of on-site diagnosis data, the data is input by the input terminal 230 through an input interface by Universal Serial Bus (USB) or a user's input, and the data is transmitted to the data management module 400 through Ethernet communication.

The network communication modules 310 and 320 should be able to collect data of each of the sensors at regular intervals. Basic requirements of the network communication modules 310 and 320 include that the entire system should be able to manage pieces of data of 30 or more electric motors, that the data management module 400 should be able to receive inputs of three or more channels, and that the data management module 400 should basically be able to use an Ethernet interface.

Therefore, a main network is configured using an Ethernet hub, and an optical-Ethernet converter or RS485-Ethernet converter is constructed under the hub. In addition, an interface is selected in consideration of an installation environment, installation location, and data transmission rate of each sensor.

(d) Data Management Module

Each piece of data generated from each of the individual sensors is transmitted or received through a different protocol, and an input cycle and processing method are different for each piece of data. Therefore, before the data management module 400 transmits the data to the database module 500, a type of each piece of data is determined by receiving the data, and appropriate processing is performed according to the type to input the data to the database module 500.

In particular, pieces of data, which are collected from the PI system, the existing diagnosis system, and the system sensor, may be processed and/or analyzed to detect whether an event occurs and may be processed and input to the database module 500.

In particular, the data management module 400 receives the pieces of data transmitted from the system sensor 213 and the transducer 223 which are mounted on the electric motor. The pieces of collected data are based on temperature sensor (RTD or thermocouple) data, and when additionally collecting data for measuring the state of the electric motor, a separate transducer is added and connected to an Ethernet switch and the pieces of collected data are collected by the data management module 400. A collection cycle is set to collect the data once per second or once per minute or at regular intervals depending on the type of data. The data management module 400 is installed indoors so that environmental resistance is not required, and the transducer 223 uses a product having environmental resistance, such as an operating temperature range, but is mounted by applying an external housing to prevent a failure due to rain or moisture.

(e) Diagnosis and Analysis Module

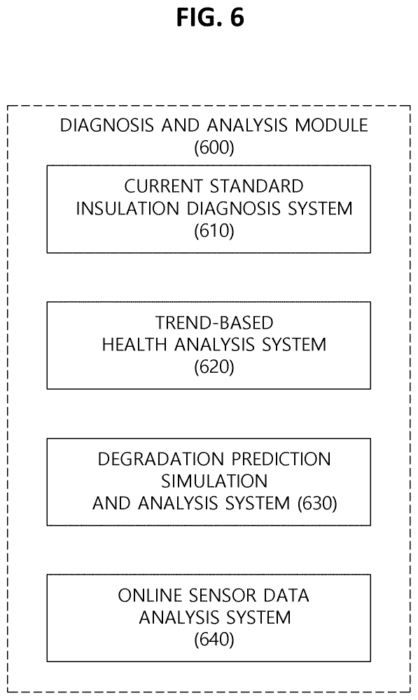

FIG. 6 is a conceptual diagram illustrating some components of the heavy electric machine health analysis platform according to another embodiment of the present invention.

Referring to FIG. 6, the diagnosis and analysis module 600 has insulation diagnosis algorithms installed thereon, drives system software, and provides a user interface. The algorithms installed on the diagnosis and analysis module 600 are implemented by a current standard insulation diagnosis system 610, a trend-based health analysis system 620, a degradation prediction simulation and analysis system 630, and an online sensor data analysis system 640. The diagnosis and analysis module 600 may drive a server client communication program to provide an interface for an administrator and an interface for a user. Detailed descriptions of the diagnosis algorithms will be given below.

Health Analysis Process

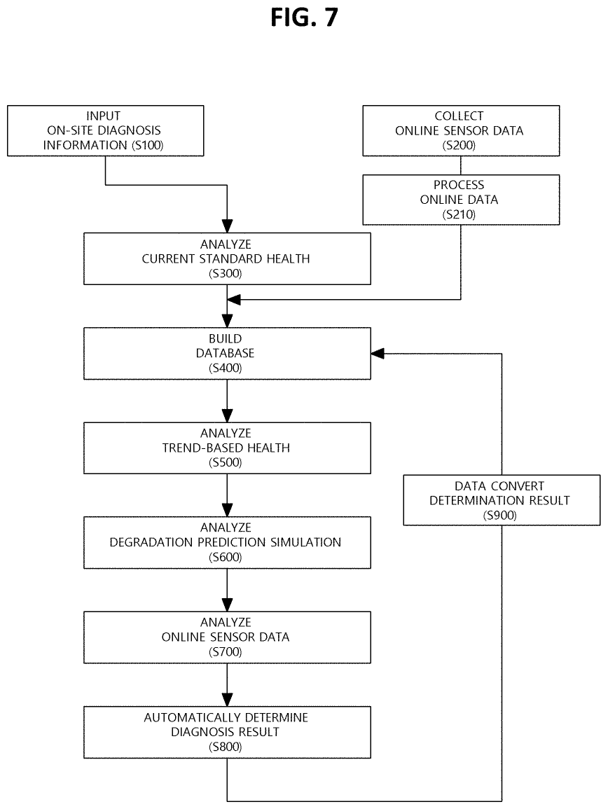

FIG. 7 is a flowchart illustrating an analysis method of the heavy electric machine health analysis platform according to another embodiment of the present invention.

Referring to FIG. 7, the analysis method according to the present embodiment includes inputting on-site diagnosis information (S100), which is an operation of collecting data, collecting online sensor data (S200), building a database to systematize the database (S400), analyzing current standard health (S300), which is an operation of analyzing health, analyzing trend-based health (S500), analyzing degradation prediction simulation (S600), analyzing the online sensor data (S700), and automatically determining a diagnosis result (S800), and the analysis method further includes processing online data (S210) when a specific event occurs using the collected online sensor data in real time, and data converting a result of the determining to build an additional database on the basis of a result of the diagnosis (S900).

When schematic processes of the analysis method are described, in the inputting of the on-site diagnosis information (S100), operation of the electric motor stops on the site, and data values directly measured in regular inspection to be performed are input.

In the analyzing of the current standard health (S300), diagnosis of health of the electric motor is automatically performed based on a current standard on the basis of the pieces of input data using the on-site measured data.

In the collecting of the online sensor data (S200), various types of data, which are collected from the mounted sensor 211, the existing diagnosis equipment 212, and the system sensor 213, are collected. The analysis method may further include the processing of the online data (S210) in which a separate event may be monitored when a specific condition is satisfied in the collecting of the online sensor data.

In the building of the database (S400), results analyzed in the analyzing of the current standard health (S300) and the pieces of data collected in the collecting of the online sensor data (S200) are comprehensively systematized and organized.

In the analyzing of the trend-based health (S500), trend-based health is analyzed based on the pieces of data built in the building of the database (S400). In this case, by predicting a failure timing of the electric motor on the basis of a result of the trend-based analysis, necessary actions and a lifetime of the electric motor are predicted.

In the analyzing of the online sensor data (S700), failure prediction and abnormal state are analyzed using the pieces of discontinuously and regularly collected online data.

In the automatic determining of the diagnosis result (S800), by comprehensively analyzing all the diagnosis results, information of the health of the electric motor, abnormal state information, and information of the failure prediction timing are comprehensively determined. The pieces of data determined in this way go through the data converting of the result of the determining (S900) in order to build an additional database and are rebuilt in the database.

The analyzing of the current standard health (S300), the analyzing of the trend-based health (S500), the analyzing of the degradation prediction simulation (S600), and the analyzing of the online sensor data (S700) have the following stepwise analysis differences.

TABLE 2
Diagnosis range and reference data for each analysis algorithm

| Requirements | Analysis method | Analysis data |
|---|---|---|
| Analyzing of current | Perform heavy electric machine | Data actually measured after |
| standard health (S300) | health diagnosis by referring to past | stopping operation of the |
| | diagnosis history of single electric | heavy electric machine on |
| | motor using on-site insulation | site |
| | diagnosis result data | |
| Analyzing of trend- | Perform trend-based health diagnosis | Data of corresponding heavy |
| based health (S500) | by referring to insulation diagnosis | electric machine and |
| | result of the same type of heavy | insulation diagnosis database |
| | electric machine from diagnosis | of the same type of heavy |
| | result of insulation diagnosis | electric machine |
| | database | |
| Analyzing of | Perform trend-based health diagnosis | Insulation diagnosis database |
| degradation prediction | by referring to insulation diagnosis | of corresponding heavy |
| simulation (S600) | result and failure history of heavy | electric machine and similar |
| | electric machine manufactured by | machine manufactured by |
| | similar machines of the same | the same manufacturer |
| | manufacturer and predict machine | |
| | learning-based insulation degradation | |
| Analyzing of online | Monitor abnormal state using pieces | Online sensor database |
| sensor data (S700) | of discontinuous and/or regularly | |
| | received sensor data without stopping | |
| | heavy electric machine | |

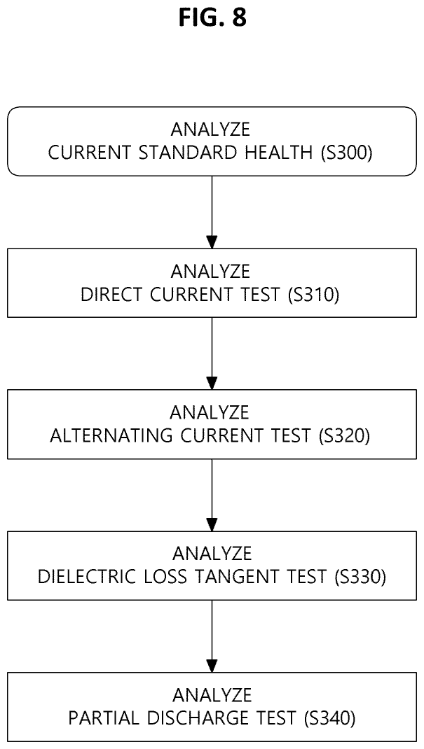

(a) Current standard health analysis FIG. 8 is a flowchart illustrating current standard health determination in the analysis method of the heavy electric machine health analysis platform according to another embodiment of the present invention.

Generally, when a new diagnosis request is received from the user, a partial discharge data analysis and evaluation algorithm based on the current standard is basically performed first. The current standard is to stop the heavy electric machine, measure necessary data once, and then determine the health of the heavy electric machine.

In the present embodiment, after the data is received in the inputting of the on-site diagnosis information (S100), the diagnosis is automatically performed based on a current standard of the Korea Electric Power Research Institute (KEPCO Research Institute) in the analyzing of the current standard health (S300).

In the inputting of the on-site diagnosis information (S100), basic information, such as a test location, a date, a manufacturer, and the like, may be input.

The analyzing of the current standard health (S300) includes analyzing a direct current test (S310), analyzing an alternating current test (S320), analyzing a dielectric loss tangent test (S330), and analyzing a partial discharge test (S340).

In the analyzing of the direct current test (S310), a polarity index test and an insulation resistance test are automatically calculated and determined. The polarity index test is a test in which a change in current according to an applied time is measured by applying an AC voltage to an insulating material. When a direct current (DC) test voltage is applied, insulation resistance of an electric motor winding varies according to the applied voltage and the applied time. Among variation ratios, a ratio of insulation resistance at one minute after a test voltage is applied to insulation resistance at ten minutes after a voltage is applied is referred to as a polarity index. Therefore, by inputting the insulation resistance for one minute and insulation resistance for ten minutes, the polarity index is automatically calculated and whether moisture is absorbed is determined.

The insulation resistance test is a test in which resistance when a DC voltage is applied to the winding is measured. The insulation resistance test is performed to determine whether there is no problem even when the heavy electric machine such as an electric motor performs insulation diagnosis before the insulation diagnosis of the electric motor is performed. In the method of measuring the insulation resistance, the DC voltage is applied to the winding, a value of the insulation resistance for one minute after the application is measured, and a criterion should be 100 MΩ or higher.

In the analyzing of the alternating current test (S320), a degree of defects inside the winding is determined. An increase in AC is caused by a micro-gap inside the insulating material and a gap between the winding and a slot. As the number of defects in the insulating material increases, an increase range of the AC increases significantly. Whether the AC is defective is determined by calculating an increase ratio of a leakage current to the applied voltage, and a criterion for defect determination is determined as normal when the increase ratio is less than or equal to 8.5% based on 6.6 kV.

In the analyzing of the dielectric loss tangent test (S330), the dielectric loss tangent is determined. A dielectric loss angles is obtained as a ratio between a charged current (le) and a measured current (I) and expressed as tan δ, and the value is referred to as dielectric loss tangent. The dielectric loss tangent test is a test for testing voids, contamination, and a state of moisture absorption inside an insulator. In the case in which an AC electric field is applied to the dielectric, when there is no defect or damage thereinside, only the charged current is present. However, in practice, frictional heat is generated due to losses caused by a leakage current and vibrations caused by electric fields, and when there are voids or defects in the insulating material, losses may occur due to partial discharge or the like. A degree of internal degradation of the insulator is measured by a difference between the charged current and the actual current generated by the loss. When a criterion for defect determination is determined as normal when the increase ratio is less than or equal to 6.5% based on 6.6 kV.

In the analyzing of the partial discharge test (S340), the partial discharge is determined. The partial discharge test is a test for testing a degradation state inside the insulator by measuring a magnitude of the partial discharge occurring in the winding insulator when an AC voltage is applied. In the partial discharge test, defects in the insulator may be identified according to the discharge pattern during the test. When a size of a partial discharge pulse is large and the number of occurrences of the partial discharge in a positive (+) portion of an AC cycle is large, the partial discharge occurs in a copper conductor, indicating that the insulating material and the conductor are separated. When the size of the partial discharge pulse is large and a size of a negative (−) pulse of the AC cycle is large, it indicates that slot discharge occurs on an outer surface of the winding or a grading paint of a terminal winding is damaged. When the size and number of partial discharges in the positive and negative polarities are the same, the discharge almost indicates that the discharge occurs due to voids or delamination inside the main insulation. The criterion for determining the defects of the partial discharge should be less than or equal to 10,000 pC based on 6.6 kV.

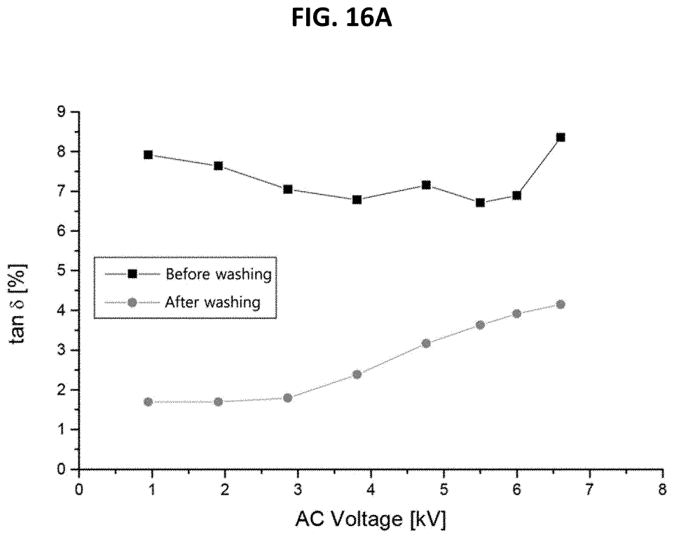

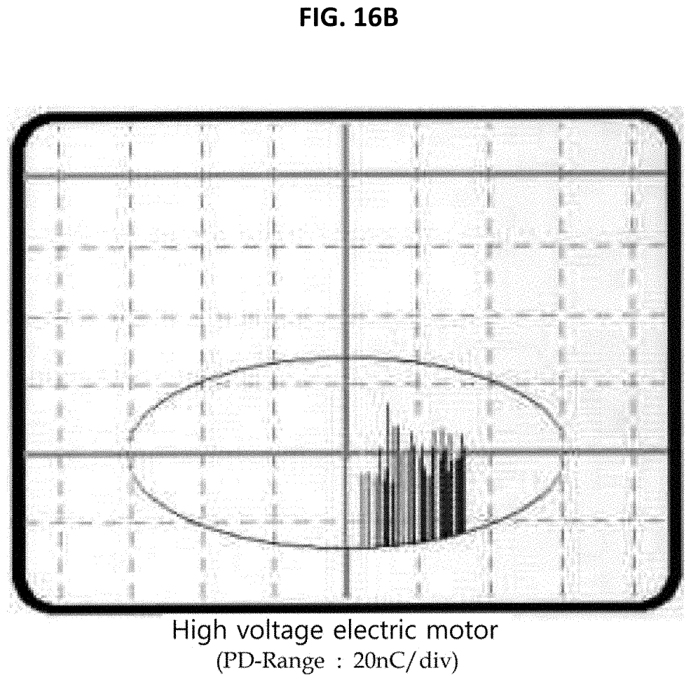

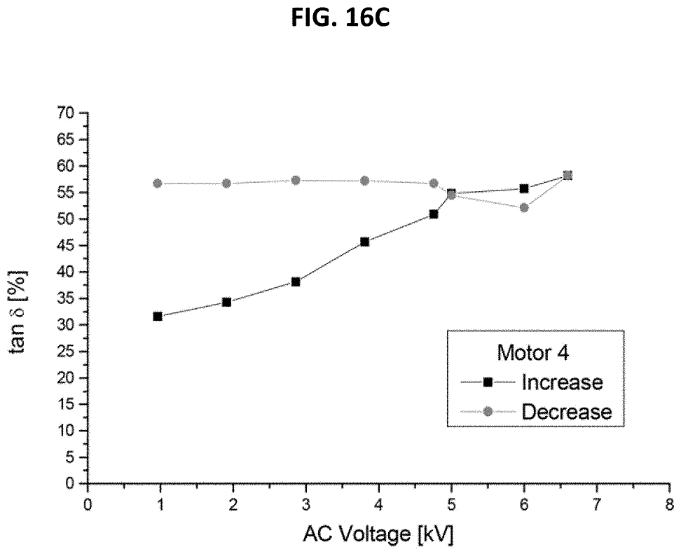

TABLE 3
Standards for evaluation of insulation state of stator windings
of generator and high-voltage electric motor

| Insulation state | Evaluation standard |
|---|---|
| Good (A) | Alternating current, dielectric loss tangent, and partial discharge are all good |
| Attention (B) | Two items among alternating current, dielectric loss tangent, and partial |
| | discharge are defective |
| Disassembly and | In the case in which partial discharge appears large at the beginning and tanδ |
| inspection (C) | voltage characteristic is as shown in FIG. 16A |
| Insulation reinforcement | Partial discharge pattern is analyzed as slot discharge as shown in FIG. 16B |
| (D) | and discharge size is 10,000 pC or more |
| Winding replacement | In the case in which alternating current, the dielectric loss tangent, and the |
| (E) | partial discharge are all defective and tanδ voltage characteristic is as shown |
| | in FIG. 16C, or when the alternating current, the dielectric loss tangent, and |
| | the partial discharge are determined as defective as a result of withstand |

(b) Online Sensor Data Analysis and Collection

On-site diagnosis insulation diagnosis is the most reliable method and requires stopping the heavy electric machine. The on-site diagnosis insulation diagnosis is regularly performed once every two years on average. However, online diagnosis may be measured while the electric motor is operated and may be used as an auxiliary indicator for detecting abnormal symptoms and supplementing data between periodic diagnosis, and it is possible to automatically estimate a location of an abnormality with partial discharge pattern recognition. It is possible to detect whether abnormality occurs suddenly between periodic diagnoses and prevent an accidental failure. The online diagnosis is used in basic trend analysis for the purpose of increasing the predictive accuracy of future progress.

The online sensor data is measured without turning off a target heavy electric machine in operation for a certain period of time as needed or as planned. Insulation degradation progresses gradually except due to a sudden circumstance such as a thunderbolt, so 24-hour monitoring is unnecessary. The online sensor data may be measured discontinuously in order to reduce facility costs required for signal lines, repeaters, etc. and reduce facility management costs according to the facility. The processing of the online data (S210) according to the present embodiment includes classifying collected data (S211), analyzing time and/or daily trends (S212), inspecting a reference and event (S213), and warning when an event occurs (S214).

In the classifying of the collected data (S211), types of the pieces of collected sensor data collected online are classified for each target heavy electric machine. Since the present analysis system utilizes the fact that the electric motor history is different for each manufacturer, it is important to accurately collect a source of the data. Therefore, the data includes the type of the electric motor for each target heavy electric machine.

In the analyzing of the time and/or daily trends (S212), the pieces of collected data are organized so that the trends may be analyzed for each time and/or date. In practice, the analysis of the time and daily data trends are performed in the analyzing of the online sensor data (S700), and in order to collect pieces of data based on the history, the pieces of data are organized for each time and date and transmitted to the data management module 400.

In the inspecting of the reference and event (S213), a sensor value is determined first. When an error occurs immediately in the sensor value measured by each sensor, the occurrence of the event is recorded and warned in a warning method set in the warning when the event occurs (S214).

For example, when a value of the AC measured as the sensor value exceeds a range from a minimum value and a maximum value, it is immediately determined as abnormal and the occurrence of the event is recorded. The warning may be generated by a preset method.

(c) Building of Database for Measurement Data

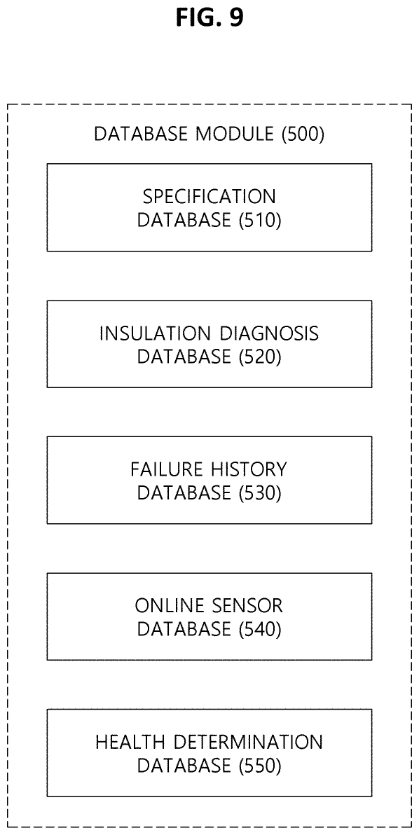

FIG. 9 is a conceptual diagram illustrating the database module applied to the analysis method of the heavy electric machine health analysis platform according to another embodiment of the present invention.

The database module 500 registers data input in a predetermined format in an internal database. Data directly input by the user is converted in a user graphic user interface (GUI) executed in the data management module 400 and transmitted to the database.

The pieces of data of the sensor and existing diagnosis system, which are collected in the data management module 400, are classified according to types thereof and transmitted in a predetermined format to the database to be registered.

The pieces of data input and managed by the database module 500 include basic information about a manufacturer, a serial number, specifications, and an installation location of the heavy electric machine, history of failure, repair, and inspection of the heavy electric machine, results of offline insulation diagnostic measurement, online sensor measurement data, data patterns, and event occurrence data.

In addition, the analysis results and analysis reports for the electric motor determined by the algorithm are input into the database module 500 again in a predetermined classification format to be registered in the database.

Referring to FIG. 9, the databases in the database module 500 include an electric motor specification database 510, an insulation diagnosis database 520, a failure history database 530, an online sensor database 540, and a health determination database 550. The electric motor specification database 510 stores specifications of the heavy electric machine such as items recorded on an electric motor name plate, such as a serial number, an output, a voltage, a current, and the number of revolutions. The insulation diagnosis database 520 stores results of on-site insulation diagnosis performed periodically. The failure history database 530 records information on failures such as insulation breakdown occurring during operation of the electric motor. The online sensor database 540 records various pieces of sensor data collected online. The health determination database 550 records results of analyzing a state of the electric motor through the algorithms of the present embodiment.

In particular, trend analysis is performed using the electric motor specification database 510, the insulation diagnosis database 520, and the failure history database 530. Further, the insulation diagnosis database 520, the failure history database 530, the online sensor database 540, and the health determination database 550 are used to predict degradation of the heavy electric machine.

The database module 500 provides a function of inputting/changing/deleting data, a function of history inquiry, a function of attachment of important files, and a function of history inquiry of insulation diagnosis data.

Additional requirements for the data are as follows.

TABLE 4
Database requirements

| Requirements | Approaches |
|---|---|
| Data processing | Classification for each heavy electric machine to be measured |
| | Automatic classification and/or conversion of collected data for DB |
| | Processing in cycles of up to 1 Hz |
| Data processing items | Start/stop history |
| | Changes in conditions such as temperature during operation |
| | Feature point analysis, period analysis, motion statistics |
| Event occurrence | Detection of occurrence of state change event exceeding a standard value |
| detection | Generation of visual/auditory alarm when an event occurs |
| Insulation diagnosis data | Automatically performing automatic DB trend analysis when a result of |
| processing | insulation diagnosis is input |
| Automatic report | Automatically generating report when data is input, and items and formats |
| generation | provided are determined in consultation with the customer within 10 |
| | minutes |

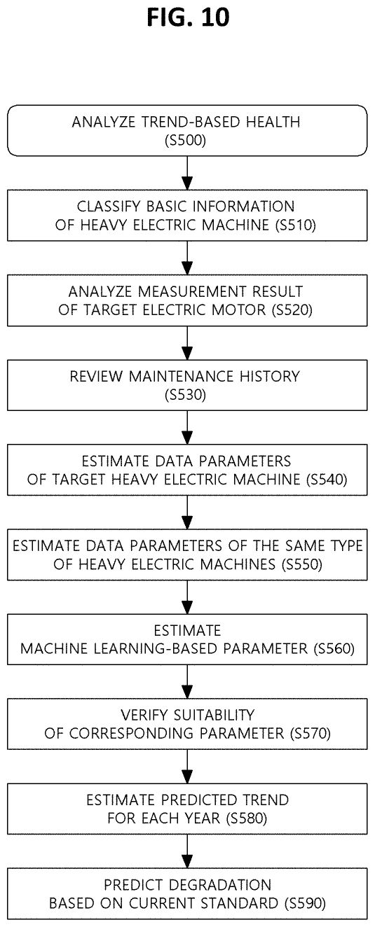

(d) Trend-based health analysis FIG. 10 is a flowchart illustrating trend-based health analysis in the analysis method of the health analysis system according to another embodiment of the present invention.

Referring to FIG. 10, when the current standard analysis is completed, the trend-based analysis is then performed in conjunction with the database. Based on insulation diagnosis history of the heavy electric machine, failure history of the heavy electric machine, electric motor operation data, the degradation progress by year is predicted and a diagnostic report is generated. The trend-based health analysis proceeds in the following order.

d-1. Classification of basic information of the heavy electric machine using the insulation diagnosis database (S510)

d-2. Extraction of measurement result of the target heavy electric machine (S520)

d-3. Review of maintenance history (S530)

d-4. Estimation of data parameters of the target heavy electric machine (S540)

d-5. Estimation of data parameters of the same type of heavy electric machines using the insulation diagnosis database (S550)

d-6. Estimation of machine learning-based parameters using the insulation diagnosis database (S560)

d-7. Verification of the suitability of the corresponding parameters using the insulation diagnosis database (S570)

d-8. Estimation of predicted trends for each year (S580)

d-9. Prediction of degradation based on current standard (S590)

The trend-based information analysis is conducted based on the results of the heavy electric machine health analysis in the past. Therefore, the basic information of the heavy electric machine is classified and the trend-based information analysis starts using the insulation diagnosis database 520 in operation S510. The basic information and the measurement results of the corresponding heavy electric machine are extracted from the insulation diagnosis database 520 in operation S520. Further, failure information and maintenance history are reviewed using the failure history database 530 in operation S530.

In the present analysis method, regression analysis is used and a Regression Model and Least squares approximation are used. This is a method of approximating an equation of a solution from the measured values. Firstly, parameters of the equation are estimated based on the target electric motor data in operation S540. In addition, secondly, a task of estimating the parameters using the pieces of data of the same type of heavy electric machines as that of the heavy electric machine stored in the insulation diagnosis database 520 is added in operation S550. In addition, thirdly, machine learning-based parameters are estimated using the insulation diagnosis database 520 in operation S560. Finally, the suitability of the corresponding parameter finally estimated is verified using the existing insulation diagnosis database 520 in operation S570.

Through the above processes, a model capable of estimating the current predicted trend of the electric motor is completed, and the predicted trends for each year are estimated over time in operation S580. Finally, degradation based on the current standard may be predicted in operation S590.

Data application examples in trend analysis A method of applying a trend-based heavy electric machine health diagnosis algorithm to actual data will be described. A target heavy electric machine is a CIDF-A motor (LB 139160081) of Dangjin Thermal Power Unit 8, which was manufactured by Hyosung in 2005. The data application example was conducted based on partial discharge values. The partial discharge values of the corresponding electric motor are as follows.

TABLE 5-1
Standards for evaluation of insulation state of stator windings
of generator and high-voltage electric motor

| | Measurement | Measurement | Measurement |
|---|---|---|---|
| Type | in 2009 | in 2011 | in 2014 |
| Partial discharge (pC) | 1,400 | 11,000 | 42,000 |

For a polynomial Dx3+Cx2+Bx+A of partial discharge data of a single motor, parameters were estimated without performing a random sample and data was estimated five years after parameter estimation and final measurement. Basically, the data was estimated for 1st, 2nd, and 3rd order functions.

TABLE 5-2
Standards for evaluation of insulation state of stator windings of
generator and high-voltage electric motor

| Number of years | Actual | | Cx2 + | Dx3 + Cx2 + |
|---|---|---|---|---|
| of operation | data | Bx + A | Bx + A | Bx + A |
| +4 | 1400 | −285.7 | 1400.0 | −12484.5 |
| +6 | 11000 | 13528.5 | 11000.0 | −22273.7 |
| +10 | 42000 | 41157.1 | 42000.0 | −54038.8 |
| +15 | | 75692.8 | 104625.0 | −84388.0 |

In the case of the partial discharge, the data may be generally expressed in the form of a quadratic function, and even the parameters estimated from randomly selected data including a first measurement result and a last measurement result may be used to estimate degradation in the next two years, and no serious error occurs.

Tables below are examples in which data extraction is applied separately by the number of years of operation.

TABLE 5
Standards for evaluation of insulation state of stator windings of
generator and high-voltage electric motor

| Number of years | Actual | | Cx2 + | Dx3 + Cx2 + |
|---|---|---|---|---|
| of operation | data | Bx + A | Bx + A | Bx + A |
| +4 | 1400 | 1400.0 | 1400.0 | 6288.2 |
| +6 | 11000 | 11000.0 | 11000.0 | 22714.4 |
| +15 | — | 54200.0 | 166885.3 | 368168.9 |

TABLE 6
Standards for evaluation of insulation state of stator windings of
generator and high-voltage electric motor

| Number of years | | | Cx2 + | Dx3 + Cx2 + |
|---|---|---|---|---|
| of operation | Actual data | Bx + A | Bx + A | Bx + A |
| +4 | 1400 | 1400 | 1400 | 3284.5 |
| +10 | 42000 | 42000 | 42000 | 55035.7 |
| +15 | — | 75833.3 | 144381.6 | 187146.1 |

TABLE 7
Standards for evaluation of insulation state of stator windings of
generator and high-voltage electric motor

| Number of years | | | Cx2 + | Dx3 + Cx2 + |
|---|---|---|---|---|
| of operation | Actual data | Bx + A | Bx + A | Bx + A |
| +6 | 11000 | 11000.0 | 10999.9 | 6518.7 |
| +10 | 42000 | 42000.0 | 41999.9 | 29065.6 |
| +15 | — | 80750.0 | 133129.7 | 96634.7 |

TABLE 8
Standards for evaluation of insulation state of stator windings of
generator and high-voltage electric motor

| Number of years | | | Cx2 + | Dx3 + Cx2 + |
|---|---|---|---|---|
| of operation | Actual data | Bx + A | Bx + A | Bx + A |
| +4 | 1400 | 1400 | 1400 | 4786.35 |
| +6 | 11000 | 11000 | 11000 | 14616.55 |
| +10 | 42000 | 42000 | 42000 | 42050.65 |
| +15 | — | 70261.1 | 148132.2 | 217316.5 |

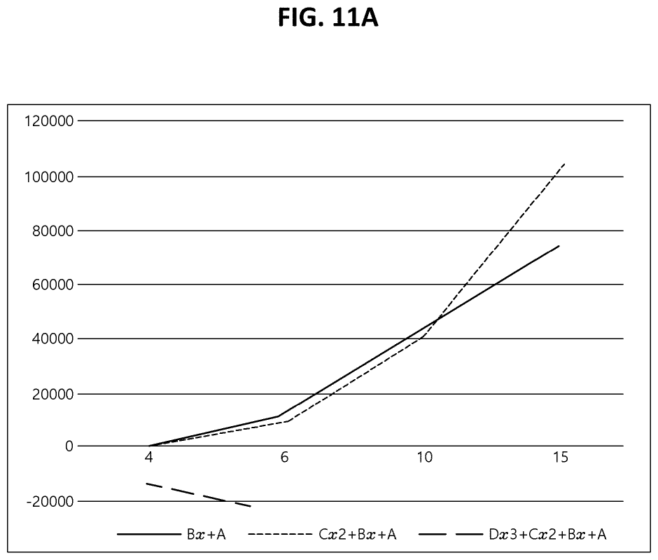

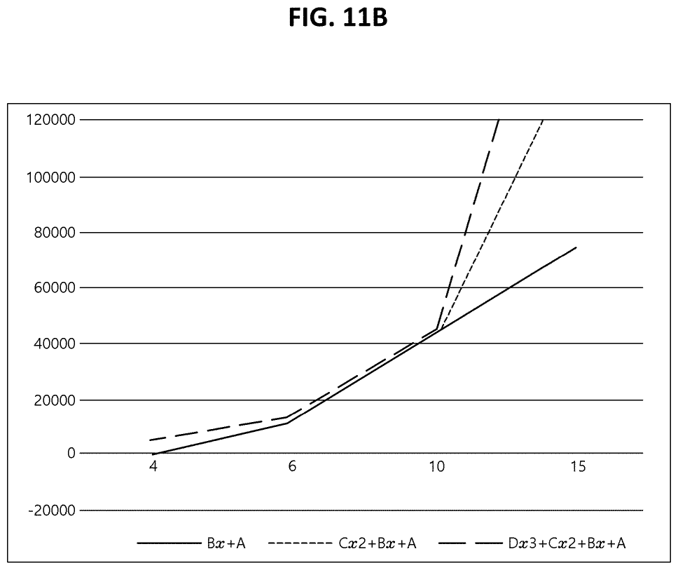

Hereinafter, the accuracy of the estimation may be improved by performing random selection and modeling of data based on a group of the same type of heavy electric machines, estimating suitability, and selecting the most suitable model by repeating random selection again. In this case, the pieces of data of the same type of heavy electric machines are applied and additional parameters for the pieces of data are modified. FIGS. 11A and 11B are graphs showing models obtained by the trend-based health analysis according to the embodiment of FIG. 10.

As shown in FIGS. 11A and 11B, when a model according to the trend-based health analysis is determined, it is possible to secure a trend of an insulation state according to a year to be predicted.

Based on finally completed parameters, the trend analysis model of the corresponding heavy electric machine is completed, and a value of the partial discharge for the predicted year may be derived by inputting a year suitable for the model.

(e) Insulation Degradation Prediction Simulation Analysis

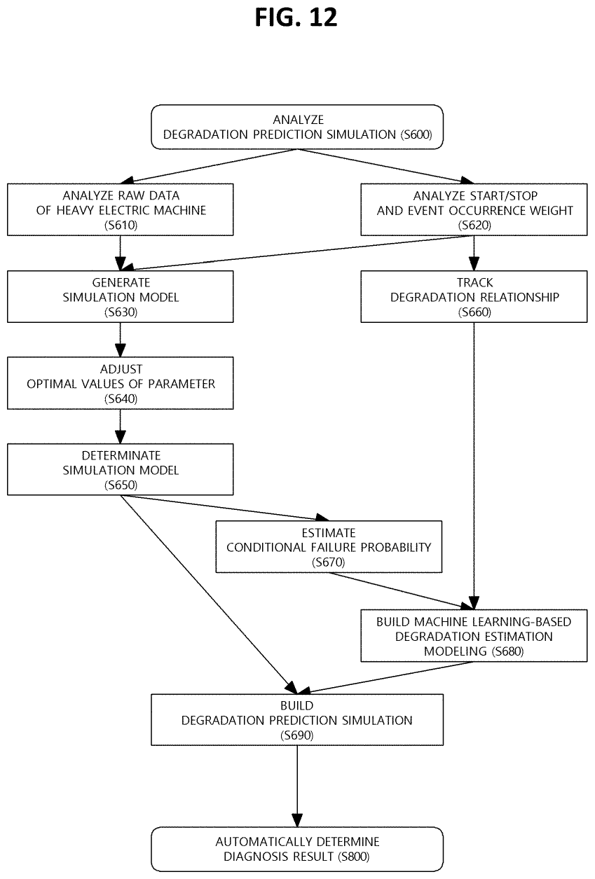

FIG. 12 is a flowchart illustrating degradation prediction simulation analysis in the analysis method of the health analysis system according to another embodiment of the present invention.

Referring to FIG. 12, when trend-based analysis is performed, degradation prediction simulation and lifetime prediction are performed. In the degradation prediction simulation, a simulation model is generated from electric motor measurement data, and preliminary simulation is performed based on a predicted trend and weight for each year to check the suitability of the model. The process therefor is as follows.

e-1. Analysis of raw data of the heavy electric machine (S610)

e-2. Analysis of (online data added) start/stop and event occurrence weight (S620)

e-3. Generation of a simulation model (S630)

e-4. Adjustment of optimal values of parameters (performance of small-scale preliminary simulation and checking of the suitability of the model) (S640)

e-5. Determination of the simulation model (S650)

e-6. Tracking of a degradation relationship (S660)

e-7. Estimation of conditional failure probability (S670)

e-8. Building of a machine learning-based degradation estimation modeling (S680)

e-9. Building of degradation prediction simulation (S690)

When the trend-based health analysis in operation S500 is completed, raw data of the heavy electric machine is analyzed using the result of the analysis in operation S610. A weight is analyzed using start/stop information and event occurrence information of an electric motor in addition to the raw data and the online sensor data in operation S620. The online sensor data, in particular, may include event information in which a heavy electric machine suddenly stops operating or a failure occurs in the model.

A simulation model may be generated based on the two groups of data in operation S630.

When the trend-based health analysis in operation S500 is analyzed based on only a single type of heavy electric machine, a range of the data applied to the degradation prediction simulation analysis in operation S600 is expanded to a range of heavy electric machines of the same manufacturer to generate a simulation model in operation S630.

Based on the generated simulation model in operation S630, optimal values of parameters of the model are adjusted in operation S640. A small-scale preliminary simulation may be performed to determine its applicability and adjust the optimal values of the parameters. In particular, as the number of pieces of data applied to the simulation increases, the sophistication of the model may increase. When the values of the parameters are optimized and the model is completed, the simulation model is determined in operation S650.

On the other hand, by utilizing the start/stop information and event occurrence information of the electric motor including the online sensor data, a degradation relationship of the corresponding electric motor is tracked in operation S660. When there is a degradation relationship according to the start/stop and event occurrence conditions of the existing heavy electric machine, modeling is generated by applying the degradation relationship to machine learning in operation S680. On the other hand, a conditional failure probability is estimated using the determined simulation model in operation S670, and the modeling is generated by applying the estimated value to machine learning in operation S680. In this way, using the machine-learned degradation estimation modeling in operation S680, when pieces of data matching a specific condition are input, a result value for determining whether a current state is normal or abnormal may be obtained, and the normal or abnormal state may be determined using the result value.

A degradation prediction simulation may be constructed using the two models of the simulation model in operation S650 and the machine learning-based degradation estimation modeling in operation S680 described above in operation S690. Based on the models, it is possible to know when the corresponding measured values change (e.g., individual values such as partial discharge values may be predicted with a simulation model), and the predicted value is determined to be normal or abnormal by applying the machine learning-based degradation estimation modeling in operation S680. The machine learning modeling will be described separately below.

Thereafter, the degradation prediction simulation is performed using the determined model. A time of failure is finally estimated through the degradation prediction simulation, and a comprehensive diagnosis report is generated based on the estimation of the time of failure and the results of preventive maintenance recommendations in operation S800.

Insulation State Diagnosis Algorithm Through Machine Learning

The diagnosis of the insulation state of heavy electric machine through machine learning modeling is to distinguish between the data that is determined to have a general inspection opinion that is normal and the data that is determined to be abnormal (attention, disassembly and inspection, insulation reinforcement, and winding replacement). To this end, a classification model is constructed using a multivariate data mining technique, and optimal parameters of the model are selected by inputting preprocessed data. As a result, an algorithm for insulation state diagnosis of the electric motor through machine learning that may be determined to be normal or abnormal for new input value is generated.

As the insulation state diagnosis algorithm through machine learning, a Mahalanobis Taguchi system (MTS) based on Mahalanobis distance and Taguchi quality engineering theory is used. The MTS expresses each piece of individual data in a unit space (Mahalanobis space (MS)) based on the normal group center point and then calculates a distance from the center point as a unit distance (Mahalanobis distance (MD)) to classify the data as a normal group or an abnormal group.

Finally, the insulation state determination algorithm for the electric motor receives nine independent variables as inputs and outputs one dependent variable. The nine independent variables include insulation resistance for one minute, polarity index determination, polarity index, dielectric loss tangent determination, dielectric loss tangent, AC determination, AC, partial high-voltage determination, and partial discharge high voltage, and the one dependent variable, which is an output, has a binary value of normal or abnormal as a comprehensive determination.

In MTS Library, a function of the insulation state determination algorithm for the electric motor is as follows.

Function 1

int MTS(double Resist1, double Polar, double Dissip, double Current, double PDHigh, string PolarRes, string DissipRes, string CurrentRes, string PDHighRes)

The following table shows a schema of a DB that manages data to determine an insulation state of a heavy electric machine.

TABLE 9
Heavy electric machine diagnosis database (DB) schema

| | Column name | TYPE | Description | Input/output |
|---|---|---|---|---|
| 1 | DataID | INT | Data registration ID | |
| 2 | AssetID | INT | Asset registration ID | |
| 3 | RelID | INT | diagnosis result ID | |
| 4 | ResAvail | ENUM (‘available,’ | Availability | |
| | | ‘expired,’ ‘usage prohibited’) | | |
| 5 | TestIter | INT | Diagnosis interval | |
| 6 | TestDate | DATE | Test date | |
| 7 | TestLoc | VARCHAR (45) | Test location | |
| 8 | Testman | VARCHAR (45) | Tester | |
| 9 | TestWeather | VARCHAR (45) | Test temperature and humidity | |
| 10 | TestRes | ENUM (‘good,’ ‘precaution,’ | Total determination | Output |
| | | ‘insulation reinforcement,’ | | |
| | | ‘re-winding,’ ‘cleaning and | | |
| | | drying,’ ‘no determination’) | | |
| 11 | TestExtra | VARCHAR (45) | Diagnosis specifics | |
| 12 | ResistRes | ENUM (‘good,’ ‘defective,’ | Insulation resistance | |
| | | ‘cleaning and drying’) | determination | |
| 13 | Resistl | DOUBLE | Insulation resistance for one | Input_1 |
| | | | minute | |
| 14 | ResistlO | DOUBLE | Insulation resistance for ten | |
| | | | minutes | |
| 15 | PolarRes | ENUM (‘good,’ ‘defective,’ | Polarity index determination | Input_6 |
| | | ‘cleaning and drying’) | | |
| 16 | Polar | DOUBLE | Polarity index | Input_2 |
| 17 | DissipRes | ENUM (‘good,’ ‘defective,’ | Dielectric loss tangent | Input_7 |
| | | ‘cleaning and drying’) | determination | |
| 18 | Dissip | DOUBLE | Dielectric loss tangent | Input_3 |
| 19 | CurrentRes | ENUM (‘good,’ ‘defective’) | Alternating current | Input_8 |
| | | | determination | |
| 20 | Current | DOUBLE | Alternating current | Input_4 |
| 21 | PDStVolt | DOUBLE | Partial discharge start voltage | |
| 22 | PDNoise | DOUBLE | Partial discharge noise | |
| 23 | PDPatt | ENUM (‘inside,’ ‘slot,’ | Partial discharge pattern | |
| | | ‘cleaning and drying’) | | |
| 24 | PDNorRes | ENUM (‘good,’ ‘defective’) | Partial phase determination | |
| 25 | PDNor | DOUBLE | Partial discharge phase voltage | |
| 26 | PDHPatt | ENUM (‘inside,’ ‘slot,’ | Partial high-voltage pattern | |
| | | ‘corona,’ ‘other’) | | |
| 27 | PDHighRes | ENUM (‘good,’ ‘defective’) | Partial high-voltage | Input_9 |
| | | | determination | |
| 28 | PDHigh | DOUBLE | Partial discharge high voltage | Input_5 |
| 29 | Nq | DOUBLE | Nq | |

The insulation state determination algorithm for the heavy electric machine calls the Mahalanobis Taguchi System (MTS) function by inputting the nine pieces of data from input_1 to input_9 based on the above DB schema and internally determines good/defective and returns values of 0 (good) and 1 (defective).

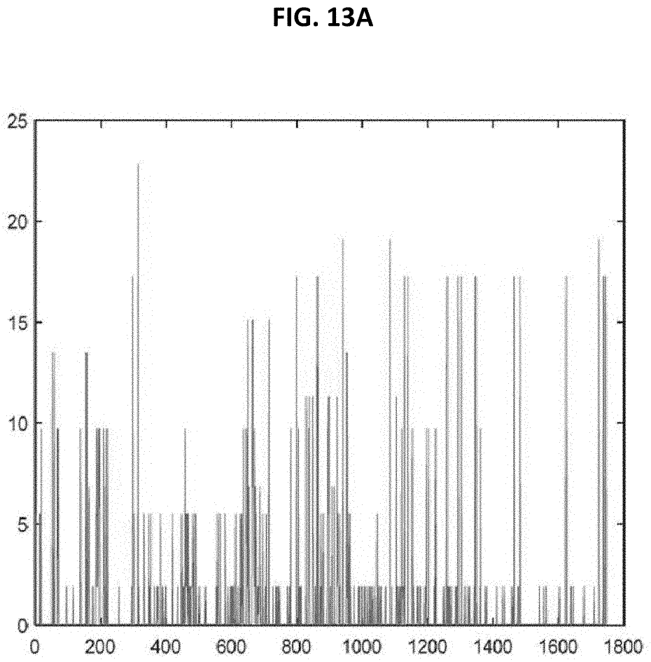

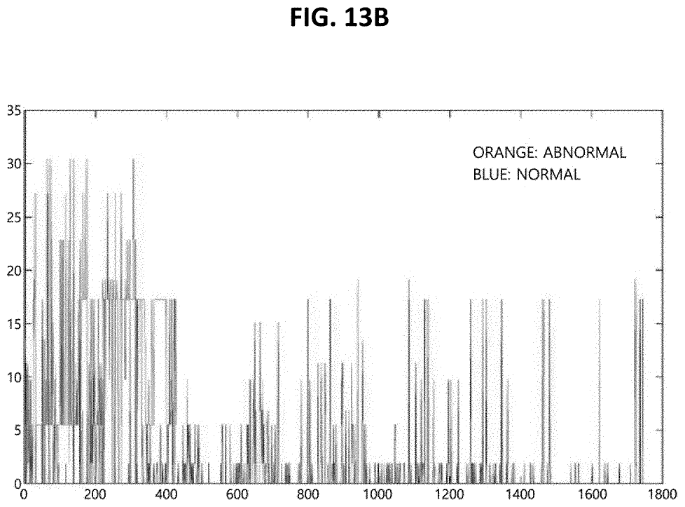

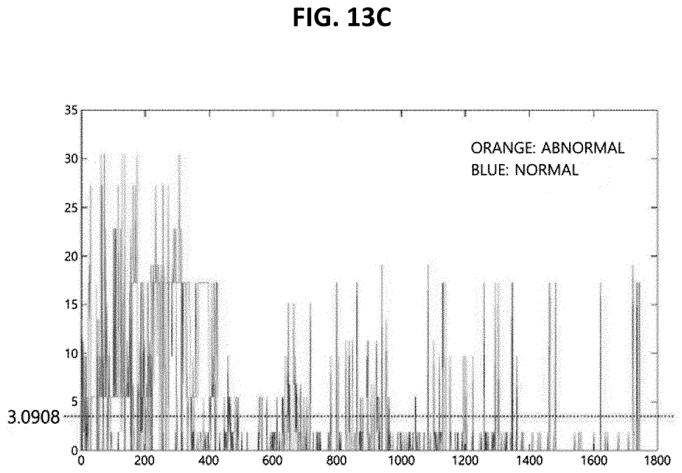

FIGS. 13A to 13C are graphs showing results of online sensor data analysis in the analysis method of the health analysis system according to another embodiment of the present invention.

FIG. 13A shows a result of calculating the MD for all pieces of data having a good overall test opinion using a preprocessed data set.

Referring to FIG. 13A, as for the unit distance (MD) result of normal data, it is measured that a mean value is 0.9994 and a std value is 2.8787. Since the mean value is close to 1.0, it may be determined as normal.

FIG. 13B shows a result of performing the MD calculation using all pieces of data whose overall test opinion is not good in advance.

Referring to FIG. 13B, the MD is calculated using all pieces of data whose overall test opinion was not good, and as a result, it is found that the normal MD may be numerically distinguished with a mean: 11.4701 and std: 7.2826. FIG. 13B shows the result of comparing the unit distance (MD) obtained as data whose overall test opinion is not good with the unit distance (MD) obtained from the existing good data. A difference occurs to the extent that classification is possible and it is possible to determine whether the MD is abnormal.

FIG. 13C shows a result of performing an accuracy analysis capable of classification using the previously obtained normal or abnormal unit distance (MD).

Referring to FIG. 13C, the distinction between normal and abnormal is a process of finding the threshold with the highest accuracy, and it can be seen that good and poor may be determined with an accuracy of 91.5% at a point at which a threshold is 3.0980. Therefore, it can be seen that the insulation status diagnosis algorithm through machine learning is an MTS-based heavy electric machine insulation status determination algorithm that may determine good and poor with an accuracy of 91.5%.

(d) Online Sensor Data Analysis

As described above, primary determination using the online sensor data may be performed in the reference inspection and event inspection in operation S213 in the online data processing in operation S210. When an event such as exceeding a set reference value occurs, it may be responded to immediately. In the analyzing operation, an in-depth analysis using a database is performed.

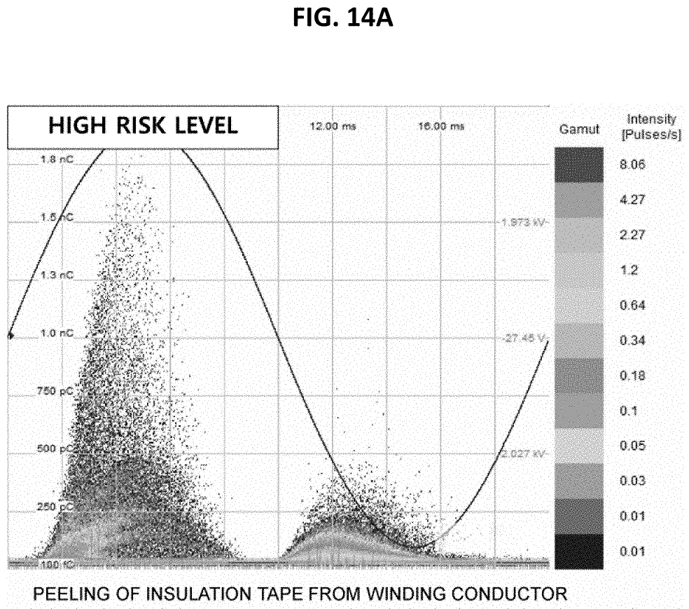

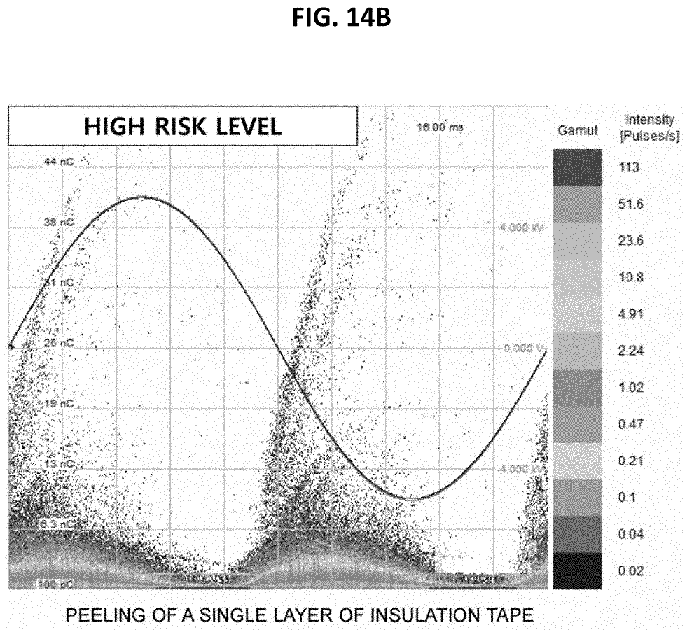

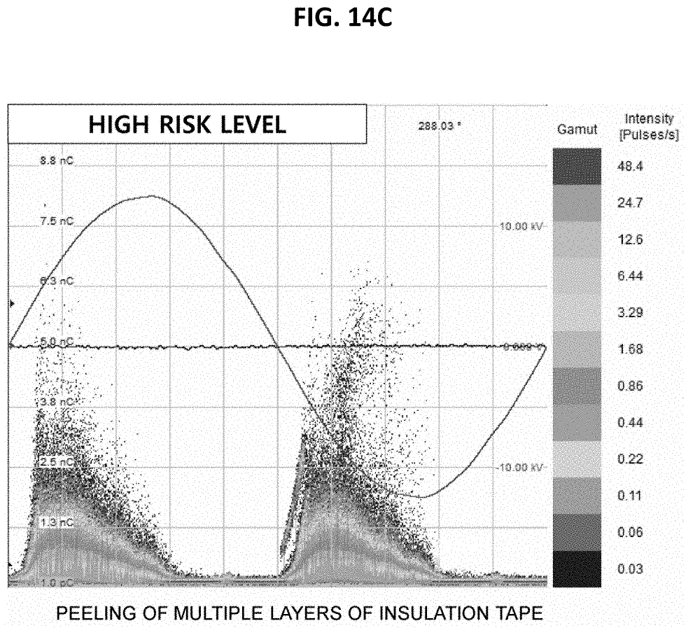

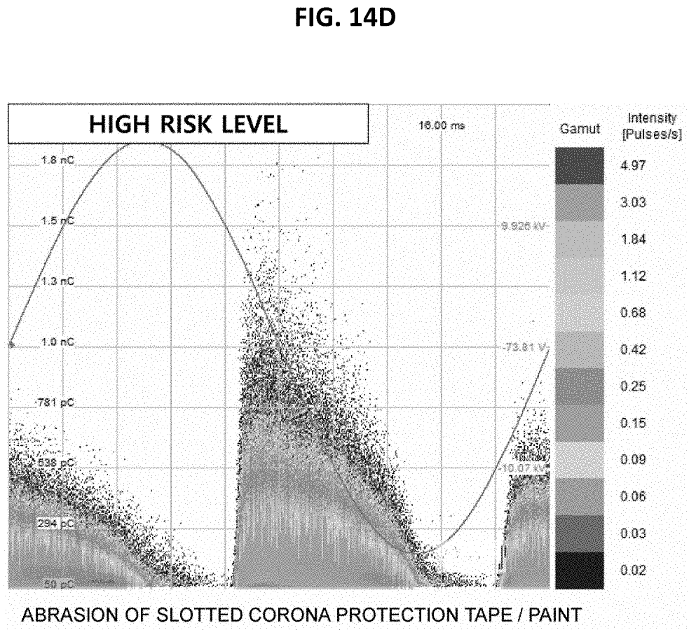

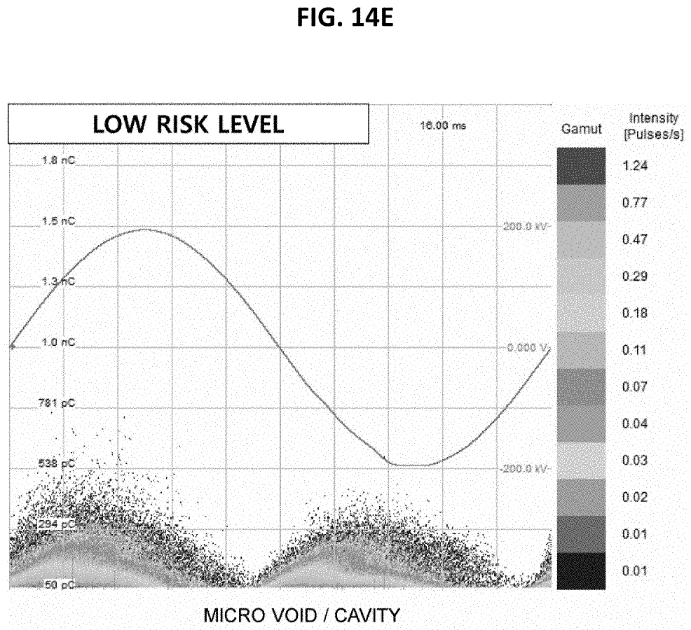

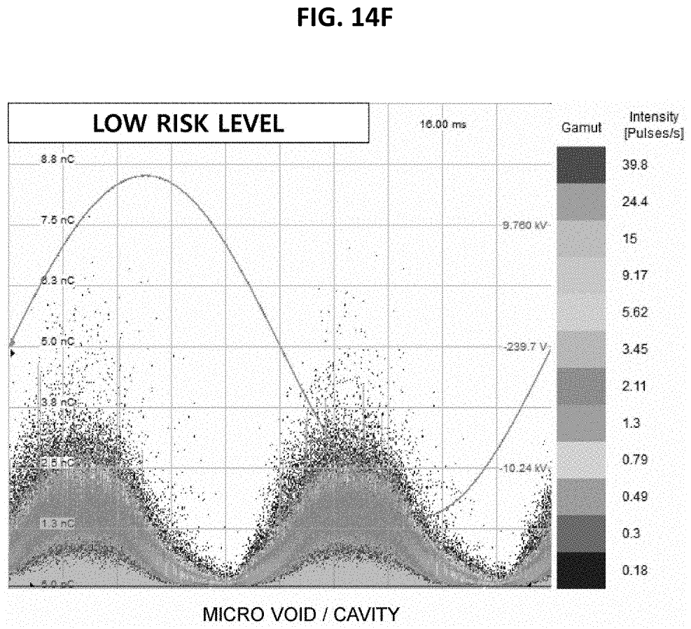

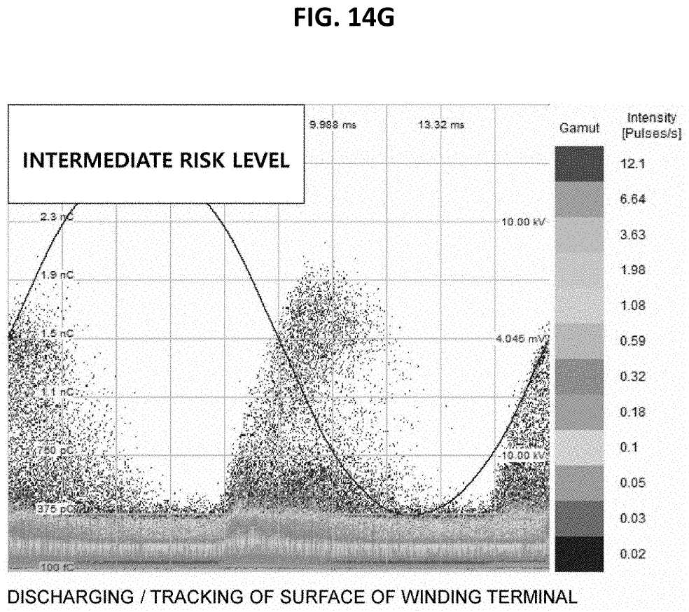

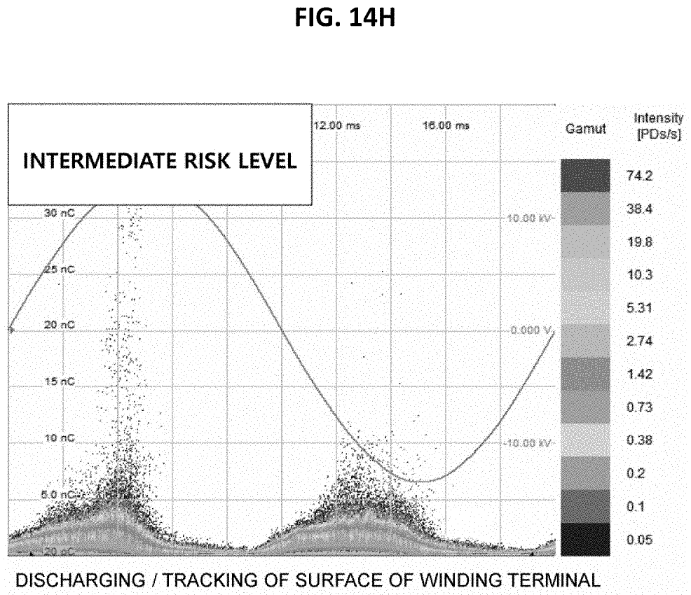

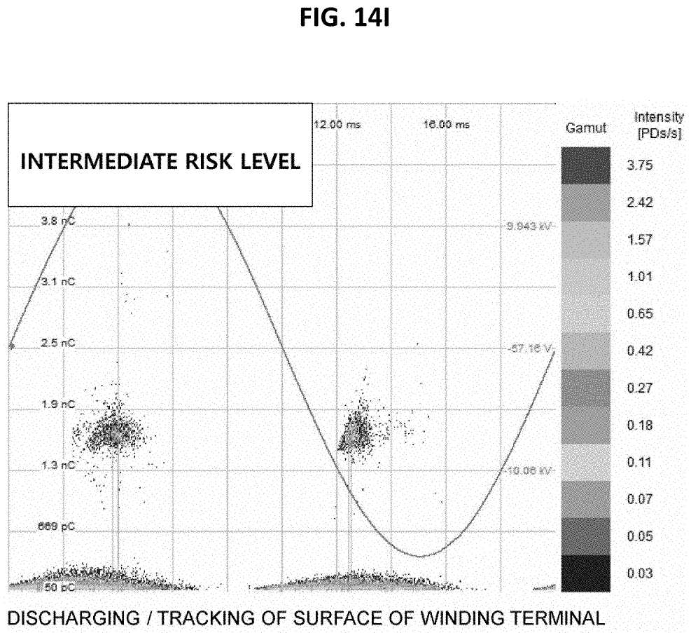

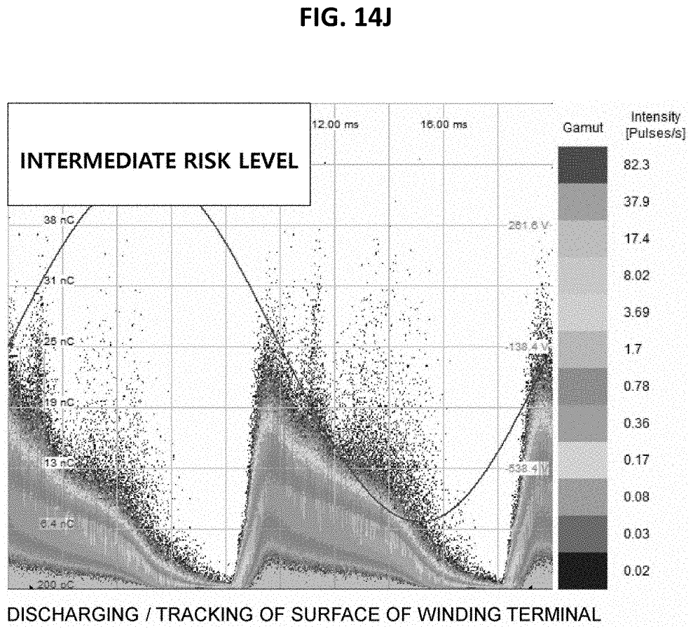

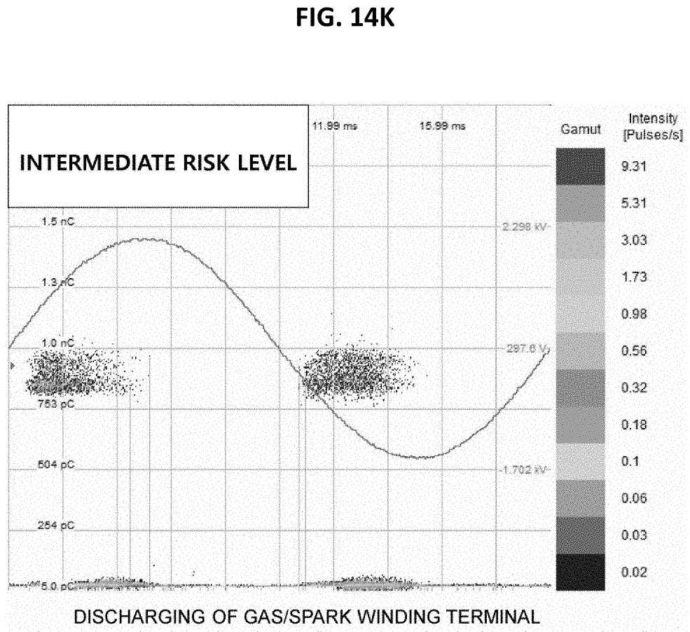

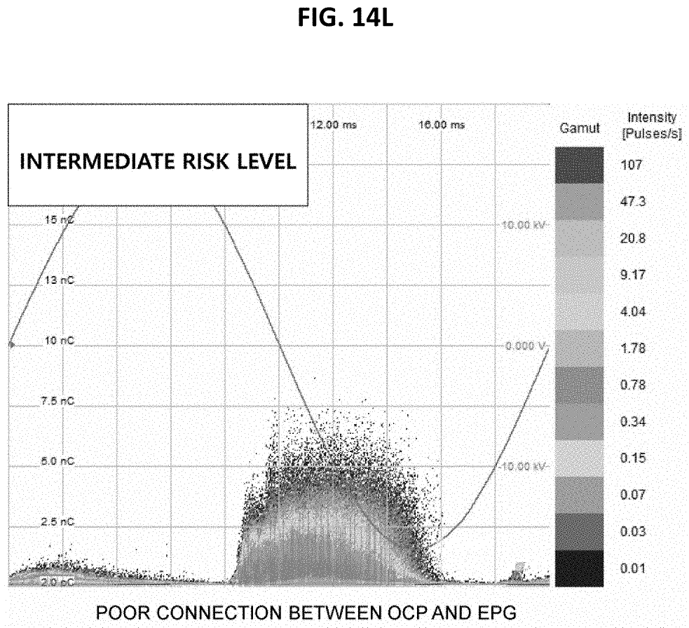

FIG. 14 shows graphs illustrating results of the online sensor data analysis in the analysis method of the health analysis system according to another embodiment of the present invention.

In the analyzing of the online sensor data (S700) according to the present embodiment, the discharge pattern is evaluated. A cause of the pattern may be identified using the discharge pattern value measured in real time or at regular intervals.

Referring to FIG. 14, according to each illustrated pattern, a risk according to the pattern and an estimated cause of occurrence of the pattern are illustrated.

The pattern types are shown from (a) to (1), and each has a high risk, low risk, or intermediate risk level. The cause of occurrence may be traced by checking the type of each pattern.

A pattern in (a) is a discharge pattern caused by peeling of the insulating tape from the winding conductor, which has a high risk.

A pattern in (b) is a discharge pattern caused by peeling of a single layer of insulating tape, which also has a high risk.

A pattern in (c) is a discharge pattern caused by peeling of multiple layers of the insulating tape, which also has a high risk.

A pattern in (d) is a discharge pattern caused by the wear of the slot corona protective tape or paint, which also has a high risk.

A pattern in (e) and a pattern in (f) are discharge patterns caused by micro-voids or cavities, which have a low risk.

Patterns in (g), (h), (i), and (j) are discharge patterns that are generated due to a cause of discharge or tracking on the surface of the winding terminal, which have an intermediate risk.

A pattern in (k) is a discharge pattern caused by discharge of the winding terminals due to gas or spark, which has an intermediate risk.

A pattern in (l) is a discharge pattern caused by a poor connection between OCP and EPG, which has an intermediate risk.

Therefore, it is possible to analyze the current state of the heavy electric machine abnormality or the degree of risk with a pattern of partial discharge that may be analyzed through the sensor data.

In addition, it is possible to increase the target of analysis by analyzing various pieces of data to be measured. In particular, through the built database, it is possible to additionally provide an algorithm capable of comparing the value of the current operation state to the past operation state and determining an abnormality when exceeding a certain ratio.

The effect of the online data analysis is that it may respond to failures or events that may occur in the period between regular site surveys. As described above, periodic inspection should be performed after stopping the operation of all motors, and thus it has to be performed every several years. There was no way to check when an abnormality occurred in a part of the heavy electric machine during the period, but through such online data analysis, blind spots that may be generated by only regular inspection may be removed.

(e) Automatic Determination of Diagnosis Result

Based on such various analysis results, diagnosis results may be automatically determined and result reports may be derived within the process.

In addition to the report based on the final result, there is a need for a method of generating a notification in case of an abnormal condition. In case of an abnormal motor condition, a notification may be provided through a beep sound and a color change of the target electric motor on a screen.

(f) Data Conversion of Determination Results

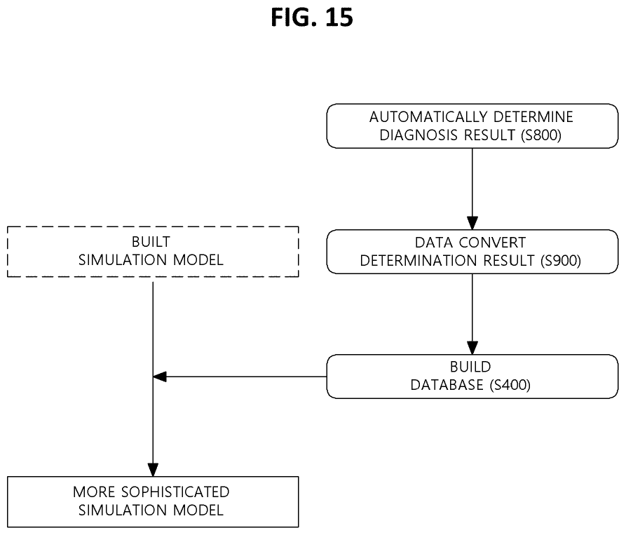

FIG. 15 is a flowchart illustrating data conversion of determination results in the analysis method of the health analysis system according to another embodiment of the present invention.

In order to improve the sophistication of the generated model in each operation, the determination result is converted into data again and provided to the database module 500, and an additional database is built again in operation S400.

In the present invention, a model and data-driven approach is applied. While the model-based method may secure high prediction accuracy with little data, it has a very limited application field because there are not many established models. However, when an accurate model may be secured, it is possible to predict future failures.

In order to maximize the advantages of the model-based method, a data-based method and a model-based method are combined and applied. The model-data-based method is a method of increasing the accuracy of the model by modeling the uncertainty occurring inside/outside based on data. The uncertainty is expressed probabilistically using the Bayesian Approach and analyzed, estimated, and updated based on the Bayes theorem.

Referring to FIG. 15, the determination result is converted into data again, and the existing data model is further refined based on the determination result. In addition, when an accident occurs before the lifetime cycle estimated by the algorithm, the lifetime prediction criteria of the algorithm may be automatically re-reflected according to the type and cause of the accident so that it may be applied to the lifetime prediction of the same type electric motor.

According to the present invention, it is possible to manage a trend of insulation diagnosis test for a heavy electric machine and, accordingly, it is possible to manage an electric motor while predicting a failure timing of the heavy electric machine.

Further, it is possible to predict a failure that may occur between periodic inspections by collecting and monitoring pieces of data of a generator and an electric motor in real time using their own system sensors in addition to an existing sensor system.

Further, it is possible to more accurately predict a failure by constructing a model in consideration of pieces of data that may predict the specificity of each heavy electric machine, such as heavy electric machines of the same type, heavy electric machines of the same manufacturer, and heavy electric machines with similar manufacturing times.

Further, since a machine learning-based model is applied, it is possible to construct a more sophisticated model as the amount of added data increases, and it is possible to construct a more sophisticated model by reprocessing various types of data, including automatic review reports, and applying the pieces of data to machine learning.

The present invention is not limited by the above-described embodiments and the accompanying drawings. It will be apparent to those skilled in the art to which the present invention belongs that components according to the present invention can be substituted, modified, and changed without departing from the scope of the present invention.

### INDUSTRIAL APPLICABILITY

The present invention is to solve the above problems, and is directed to providing a platform for analyzing health of a heavy electric machine, in which various types of data related to a test for the heavy electric machine are managed and a time of failure is predicted using the same, and an analysis method using the same.

What is claimed is:

1. A platform for analyzing health of a heavy electric machine, which is a heavy electric machine health analysis platform (1000), the platform comprising:
a sensor module (210);
a data collection module (220) configured to collect pieces of data from the sensor module (210);
a data management module (400) configured to receive and manage pieces of data from the data collection module (220);
a database module (500) configured to record the pieces of data received from the data management module (400); and
a diagnosis and analysis module (600) configured to perform diagnosis of an electric motor by applying the pieces of data recorded in the database module (500),
wherein the diagnosis and analysis module (600) includes a current standard insulation diagnosis system (610) configured to diagnose health of the electric machine on the basis of the pieces of received data,
a trend-based health analysis system (620) configured to estimate and analyze a predicted trend for each year in conjunction with a database of the database module (500),
a degradation prediction simulation and analysis system (630) configured to generate a simulation model and analyze degradation, and
an online sensor data analysis system (640) configured to analyze using the provided online data.

2. The platform of claim 1, further comprising:
a payment module (110) configured to perform payment between external users;
a report and data management module (120) configured to collect and/or provide reports and pieces of data from and/or to the external users; and
a warning module (130) configured to warn the outside about an event when the event occurs.

3. The platform of claim 1, wherein:
the sensor module (210) includes a mounting sensor (211), diagnosis equipment (212), and a system sensor (213) which are mounted on the heavy electric machine; and
the data collection module (220) includes a PI system (221) configured to collect pieces of data of the mounting sensor (211), a general diagnosis system (222) linked with the diagnosis equipment (212), and a transducer (223) linked with the system sensor (213).

4. The platform of claim 1, wherein the database module (500) includes an electric motor specification database (510), an insulation diagnosis database (520), a failure history database (530), an online sensor database (540), and a health determination database (550).

5. The platform of claim 4, wherein the trend-based health analysis system (620) estimates a predicted trend for each year by estimating the same type of heavy electric machine data parameters using a target electric motor data parameter and the insulation diagnosis database (520).

6. The platform of claim 1, wherein the degradation prediction simulation and analysis system (630) includes a simulation model and a machine learning-based degradation estimation modeling.

7. The platform of claim 6, wherein the constructed machine learning-based degradation estimation modeling is modeling in which each piece of individual data is expressed in a unit space (Mahalanobis space (MS)) based on a normal group center point and then it is determined that the pieces of data are normal or abnormal by measuring a unit distance (Mahalanobis distance (MD)) indicating how far the pieces of data are from the center point.

8. The platform of claim 7, wherein independent variables of the each piece of individual data include a value of an insulation resistance measured for one minute, a value of polarity index determination, a value of a polarity index, a value of dielectric loss tangent determination, a value of a dielectric loss tangent, a value of alternating current (AC) determination, a value of an AC, a value of partial high voltage determination, and a value of a partial discharge high voltage.

9. The platform of claim 1, wherein the heavy electric machine includes a generator, a transformer, and an electric motor.

10. A method of analyzing health of a heavy electric machine, the method comprising:
an operation (S100) of inputting on-site diagnosis information in which pieces of data collected in a site are received in a state in which operation of the heavy electric machine stops;
an operation (S200) of collecting pieces of online sensor data in which pieces of data of installed sensors are periodically/discontinuously collected through a sensor module (210) and a data collection module (220);
an operation (S400) of building a database using the data in the operation (S100) of the inputting of the on-site diagnosis information and the data in the operation (S200) of the collecting of the pieces of online sensor data;
an operation (S300) of analyzing the current standard health which includes an operation (S310) of analyzing a direct current test, an operation (S320) of analyzing an alternating current test, an operation (S330) of analyzing a dielectric loss tangent test, and an operation (S340) of analyzing a partial discharge test and in which health of a current standard heavy electric machine is diagnosed based on the pieces of data input in the operation (S100) of the inputting of the on-site diagnosis information;
an operation (S500) of analyzing trend-based health in which a predicted trend for each year is estimated in connection with the database built in the operation (S400) of the building of the database and the health is analyzed;
an operation (S600) of analyzing degradation prediction simulation in which a simulation model is generated and the health of the heavy electric machine is analyzed;
an operation (S700) of analyzing the pieces of online sensor data in which the health of the heavy electric machine is analyzed using the pieces of online sensor data collected in the operation (S200) of the collecting of the online sensor data; and
an operation (S800) of automatically determining a diagnosis result.

11. The method of claim 10, wherein:
in the operation (S300) of the analyzing of the current standard health, the current standard health is analyzed using the pieces of data input in the operation (S100) of the inputting of the on-site diagnosis information;
in the operation (S500) of the analyzing of the trend-based health, the trend-based health is analyzed using the pieces of data input in the operation (S100) of the inputting of the on-site diagnosis and the pieces of data of the heavy electric machine which are the same type as those of the field diagnosed heavy electric machine; and
in the operation (S600) of the analyzing of the degradation prediction simulation, the degradation prediction simulation is analyzed using the pieces of data input in the operation (S100) of the inputting of the on-site diagnosis, the pieces of data of the heavy electric machine which are the same type as those of the field diagnosed heavy electric machine, and the pieces of data of the heavy electric machine of the same manufacturer as and a similar period to the field diagnosed heavy electric machine.

12. The method of claim 10, wherein the operation (S200) of the collecting of the online sensor data includes:
an operation (S211) of classifying the pieces of collected sensor data in which the pieces of collected sensor data collected online are classified into data for each target heavy electric machine;
an operation (S212) of organizing time and/or daily trends in which the trends are organized so as to be analyzed by time and date;
an operation (S213) of inspecting a reference and an event in which values of the sensors are firstly determined and an event is detected; and
an operation (S214) of warning when an event occurs in which a warning is generated when the event occurs.

13. The method of claim 10, wherein the database built in the operation (S400) of the building of the database includes a heavy electric machine specification database (510), an insulation diagnosis database (520), a failure history database (530), an online sensor database (540), and a health determination database (550).

14. The method of claim 10, wherein the operation (S500) of the analyzing of the trend-based health includes:
an operation (S510) of classifying basic information of the heavy electric machine using the insulation diagnosis database;
an operation (S520) of extracting a measurement result of a target heavy electric machine;
an operation (S530) of reviewing a maintenance history;
an operation (S540) of estimating a target electric motor data parameter;
an operation (S550) of estimating the same type of heavy electric machine data parameters using the insulation diagnosis database;
an operation (S560) of estimating a machine learning-based parameter using the insulation diagnosis database;
an operation (S570) of verifying suitability of the corresponding parameter using the insulation diagnosis database;
an operation (S580) of estimating a predicted trend for each year; and
an operation (S590) of predicting degradation based on a current standard.

15. The method of claim 10, wherein the operation (S600) of the analyzing of the degradation prediction simulation includes:
an operation (S610) of analyzing raw data of the heavy electric machine;
an operation (S620) of analyzing start and/or stop and event occurrence weight in which the pieces of online data collected in the operation (S200) of the collecting of the online sensor data are added;
an operation (S630) of generating a simulation model;
an operation (S640) of adjusting optimal values of parameters of the simulation model generated in the operation (S630) of the generating of the simulation model;
an operation (S650) of determining the simulation model in which the model is determined with the values adjusted in the operation (S640) of the adjusting of the optimal values of the parameter;
an operation (S660) of tracking a degradation relationship in which a relationship of the event is tracked based on the result values analyzed in the operation (S620) of the analyzing of start and/or stop and event occurrence weight;
an operation (S670) of estimating conditional failure probability in which failure probability is estimated using the simulation model determined in the operation (S650) of the determining of the simulation model;
an operation (S680) of building a machine learning-based degradation estimation modeling in which a machine learning-based degradation modeling is built; and
an operation (S690) of building a degradation prediction simulation in which a final simulation is completed using the simulation model determined in the operation (S650) of the determining of the simulation model and the machine learning-based degradation estimation modeling determined in the operation (S680) of the building of the machine learning-based degradation estimation modeling.

16. The method of claim 10, wherein in the operation (S680) of the building of the machine learning-based degradation estimation modeling, modeling is formed in which each piece of individual data is expressed in a unit space (Mahalanobis space (MS)) based on a normal group center point and then it is determined that the pieces of data are normal or abnormal by measuring a unit distance (Mahalanobis distance (MD)) indicating how far the pieces of data are from the center point.

17. The method of claim 16, wherein independent variables of the each piece of individual data include a value of an insulation resistance measured for one minute, a value of polarity index determination, a value of a polarity index, a value of dielectric loss tangent determination, a value of a dielectric loss tangent, a value of alternating current determination, a value of an alternating current, a value of partial high voltage determination, and a value of a partial discharge high voltage.

18. The method of claim 10, wherein in the operation (S700) of the analyzing of the online sensor data, a value of a discharge pattern is extracted from the pieces of online sensor data collected in the operation (S200) of the collecting of the online sensor data and a risk and a cause of occurrence are estimated according to the discharge pattern.

19. The method of claim 10, further comprising an operation (S900) of converting a determining result data for re-applying the result determined in the operation (S800) of the automatic determining of the diagnosis result to the operation (S400) of the building of the database.

20. The method of claim 19, wherein the simulation model generated in the operation (S600) of the analyzing of the degradation prediction simulation is updated to a more sophisticated model by a model and data-driven approach using the data generated in the operation (S900) of the converting of the determining result data.
